(19) United States
(12) Patent Application Publication
(10) Pub. No.: US 2025/0216600 A1
(43) Pub. Date: Jul. 3, 2025

(54) METHOD OF FORMING AN INTEGRATED OPTICAL CHIP PACKAGE DEVICE AND METHOD OF FORMING SAME

(71) Applicant: Taiwan Semiconductor Manufacturing Co., Ltd., Hsinchu (TW)

(72) Inventors: Yu-Hung Lin, Taichung City (TW); Ren-Fen Tsui, Taipei (TW); Kuo-Chung Yee, Taoyuan City (TW); Chen-Hua Yu, Hsinchu (TW)

(21) Appl. No.: 18/399,405

(22) Filed: Dec. 28, 2023

(51) Int. Cl. G02B 6/12; G02B 6/136; H01L 23/00; H01L 23/28; H01L 23/538; H01L 25/16

(52) U.S. Cl. CPC G02B 6/12004; G02B 6/136; H01L 23/28; H01L 23/5383; H01L 23/5384; H01L 24/08; H01L 25/167; G02B 2006/12121; H01L 2224/08225; H01L 2224/82896; H01L 2224/82897

(57) ABSTRACT

A semiconductor device and method of manufacturing are disclosed. The semiconductor device includes an optical die, a laser die, and an interposer. The optical die has photonic integrated circuits (PICs), electronic integrated circuits (EICs), and one or more first coupling waveguides. The laser die has at least one laser diode and one or more second coupling waveguides. The optical die and the laser die are bonded to a first side of the interposer using a metal-to-metal bonding, where at least one of the one or more first coupling waveguides is optically aligned with at least one of the one or more second coupling waveguides. An optical glue fills a gap between the aligned at least one of the one or more first coupling waveguides and the at least one of the one or more second coupling waveguides.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

Maintaining alignment between optical components within a semiconductor device is particularly advantageous for efficient and high quality transfer of light energy. However, known methods of fabrication can result in misalignment due to relative motion between components as a result of the fabrication process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a first integrated package with an embedded laser die and COUPE die, in accordance with some embodiments.

FIGS. 2-9 illustrate formation and preparation of a COUPE die for integration into the first optical package, in accordance with some embodiments.

FIGS. 10-14 illustrate formation and preparation of a laser die for integration into the first optical package, in accordance with some embodiments.

FIGS. 15-19B illustrate the bonding of the COUPE die and laser die onto an interposer and of the unit into the first integrated package, in accordance with some embodiments.

FIGS. 20A-C illustrate inclusion of the first optical package in various devices, in accordance with some embodiments.

### DETAILED DESCRIPTION OF ILLUSTRATIVE EMBODIMENTS

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which one or more laser dies and one or more compact universal photonic engine (COUPE) dies are embedded in an integrated package. Light from the laser dies is coupled to other optical devices, including the COUPE die. However, the embodiments presented herein are intended to be illustrative and are not intended to limit the embodiments to the precise descriptions as discussed. Rather, the embodiments discussed may be incorporated into a wide variety of implementations, and all such implementations are fully intended to be included within the scope of the embodiments.

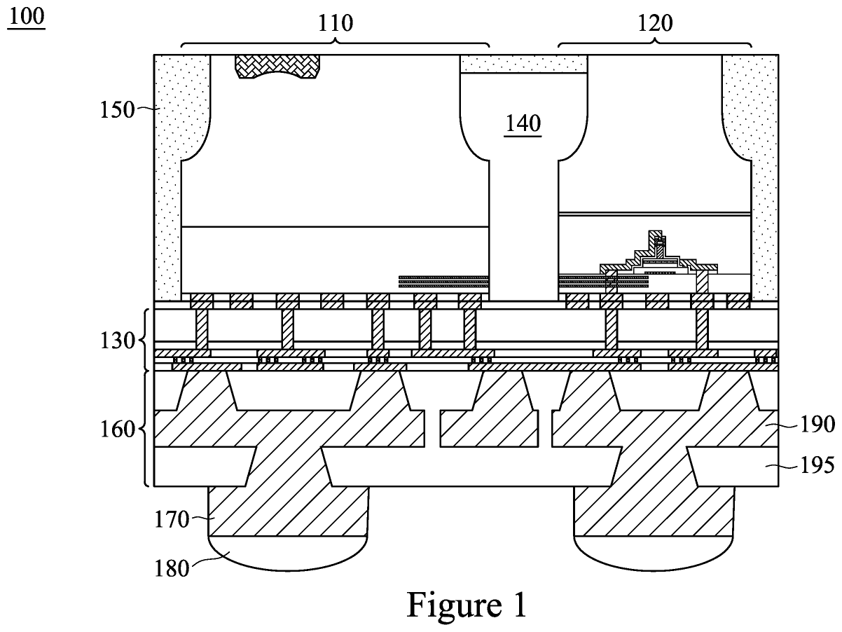

With reference now to FIG. 1, there is illustrated an initial structure of a first integrated package 100, in accordance with some embodiments. In the particular embodiment illustrated in FIG. 1, the first integrated package 100 comprises an interposer 130, one or more COUPE dies 110, one or more laser dies 120, an optical molding glue 140 between the one or more COUPE dies 110 and one or more laser dies 120, a molding portion 150, a redistributive layer portion 160, a set of external connectors 170 and solder portions 180. Additional devices not shown may be integrated into the first integrated package 100, and the embodiment shown is not limiting on the devices which may be present.

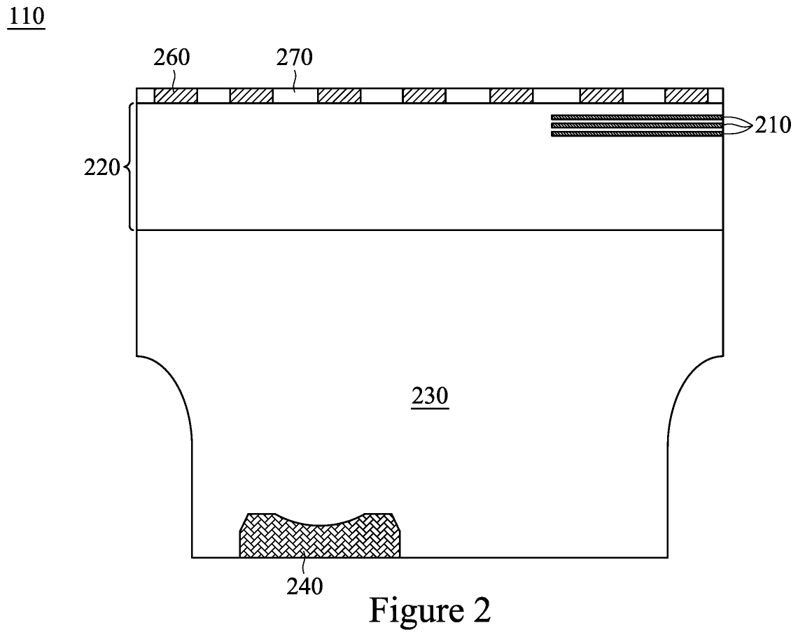

FIG. 2 illustrates an exemplary COUPE die in accordance with some embodiments. A COUPE die 110 may comprise a first active portion 220 on a first support substrate 230. In some embodiments the first active portion 220 of the COUPE die 110 comprises both photonic integrated circuits (PICs—e.g., circuits that include optical devices that utilize light energy) (not shown), electronic integrated circuit (EICs—e.g., devices without optical devices) (not shown), and one or more first coupling waveguides 210. The COUPE die 110 additionally includes a bonding layer comprising first copper bonding pads 260 and a first dielectric material 270.

In some embodiments the one or more PICs may include optical components such as additional optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used.

In some embodiments, the first coupling waveguides 210 may be comprised of silicon nitride. The first coupling waveguides 210 may be multi-layer, multi-line, or trench style waveguides. For example, in the embodiment shown in FIG. 2, three-multi-layer waveguides are shown. In an embodiment the first coupling waveguides 210 may be patterned using, e.g., one or more photolithographic masking and etching processes. However, any suitable method of patterning the material for the first coupling waveguides 210 may be utilized. For example, implantation processes, additional deposition and patterning processes for different materials, combinations of all of these processes, or the like, can be utilized, and all such combinations are fully intended to be included within the scope of the embodiments.

In an embodiment the first support substrate 230 may be a support material that is transparent to the wavelength of light that is desired to be used, such as silicon, and may be attached using, e.g., an adhesive (not separately illustrated in FIG. 2). However, in other embodiments the first support substrate 230 may be bonded to the first active portion 220 of the COUPE die 110 using, e.g., a bonding process. Any suitable method of attaching the first support substrate 230 may be used. In the described embodiments, first active portion 220 of the COUPE die 110 is formed on a bulk substrate (not shown), such as a bulk silicon or other semiconductor material wafer, a silicon-on-insulator (SOI) wafer, or the like, which bulk wafer is then removed (e.g. by back side thinning, etching or the like) after being mounted to first support substrate 230. As the process steps for forming first active portion 220 are known, they are not repeated here for the sake of clarity and brevity. It is within the contemplated scope of the current disclosure, however, that first support substrate 230 could be bulk wafer in and upon which first active portion 220 of the COUPE die 110 is originally formed (in which case the above-described step of bonding first active portion 220 of COUPE die 110 to first support substrate 230 is not necessary).

The first support substrate 230 may additionally comprise a coupling lens 240 positioned to facilitate movement from an optical fiber (not illustrated in FIG. 2) to a grating coupler within, e.g., the first active portion 220 of the COUPE die 110. In an embodiment the coupling lens 240 may be formed by shaping the material of the support substrate (e.g., silicon) using masking and etching processes. However, any suitable process may be utilized.

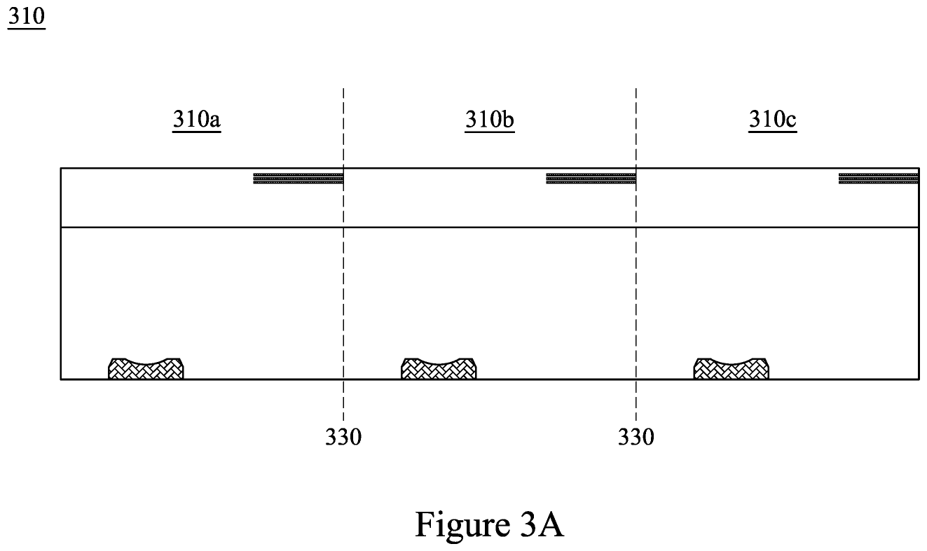

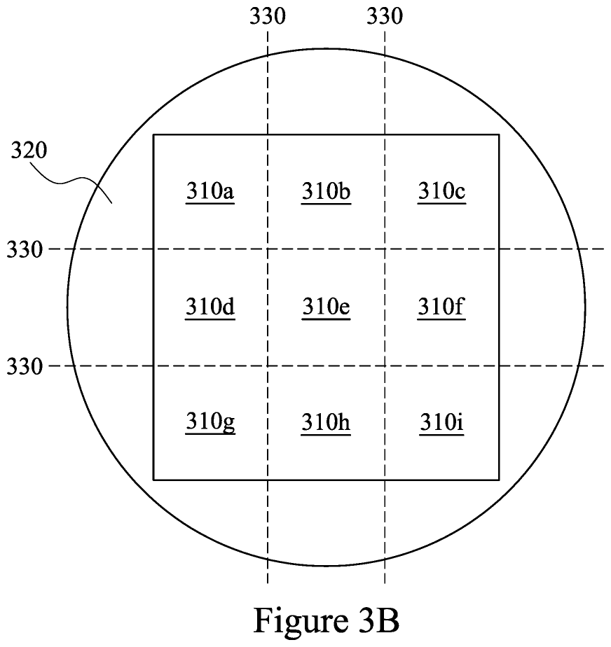

As shown in FIG. 3A, in some embodiments, the COUPE die 110 may be fabricated as part of a larger wafer or panel form fabrication process having multiple die regions such as COUPE die regions 310a, 310b, and 310c (collectively 310). For example, FIG. 3B illustrates a circular wafer shape 320 with nine COUPE die regions 310a trough 310i. In the embodiment shown, nine COUPE dies are included on the wafer allowing for nine COUPE dies 110 to be fabricated on a single wafer and singulated. Fewer or more die regions may be utilized on a single wafer in other embodiments.

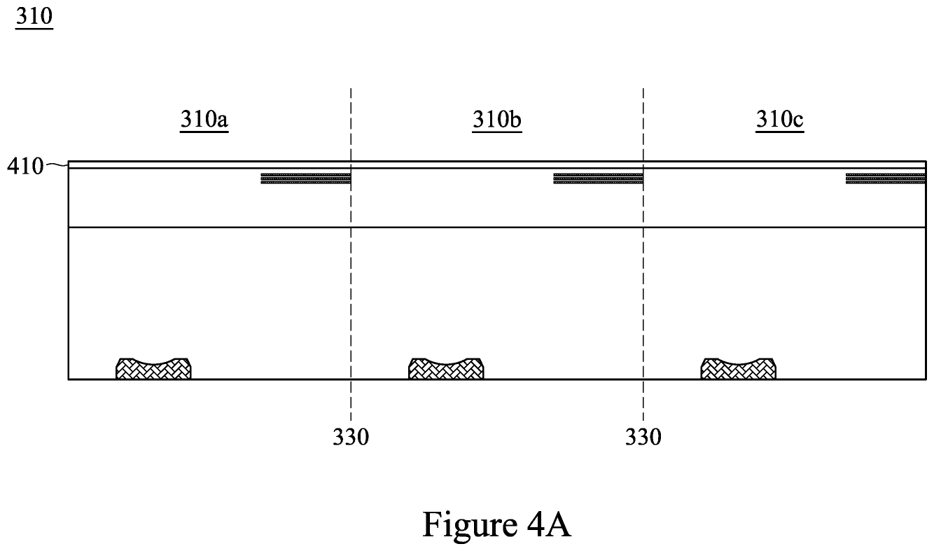

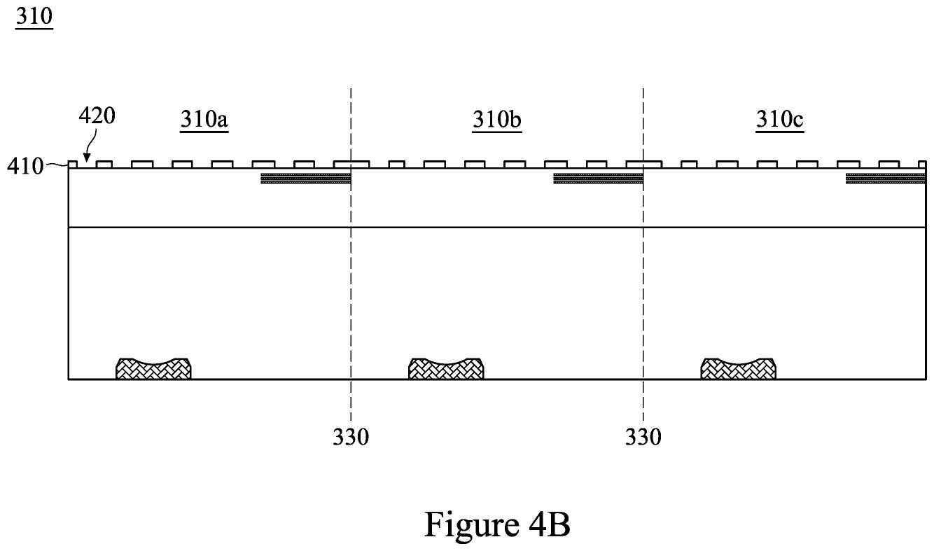

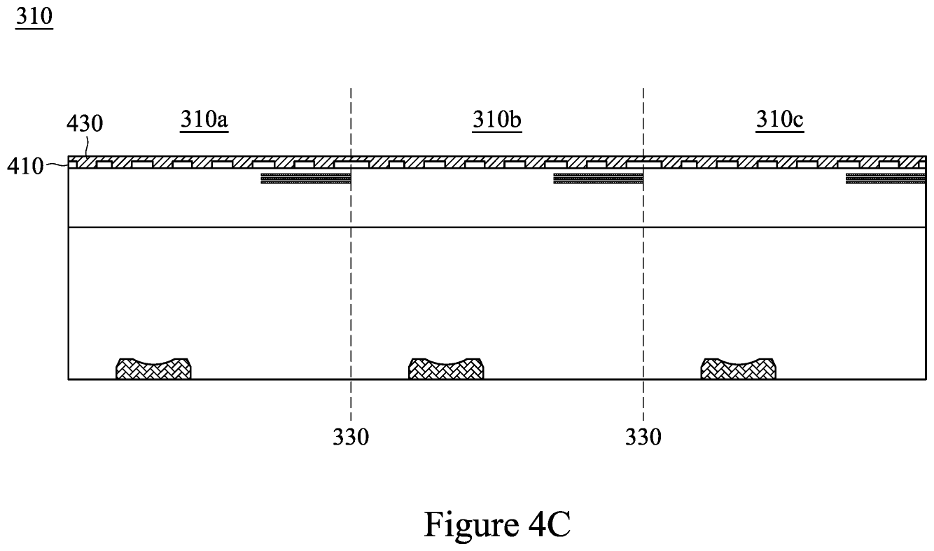

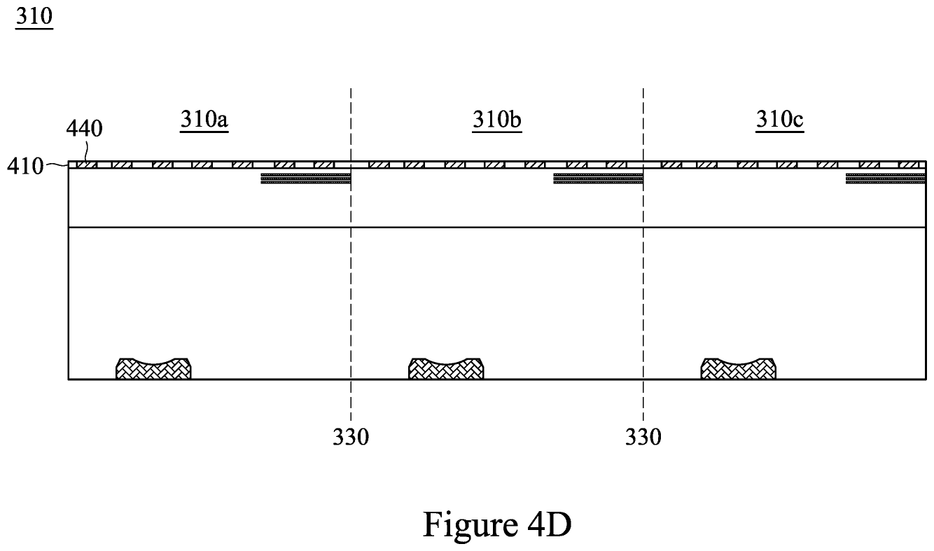

FIGS. 4A-4D show an exemplary embodiment for the preparation of the COUPE die 110 for bonding layer prior to singulation of the first integrated package 100.

In accordance with some embodiments, as shown in FIG. 4A, a first bonding layer 410 is formed of a first dielectric material such as silicon oxide, silicon nitride, or the like. The first dielectric material may be deposited using any suitable method, such as CVD, high-density plasma chemical vapor deposition (HDPCVD), PVD, atomic layer deposition (ALD), or the like. However, any suitable materials and deposition processes may be utilized. The first bonding layer 410 may later be used for a dielectric-to-dielectric and metal-to-metal bonding between the COUPE die 110 and the interposer 130.

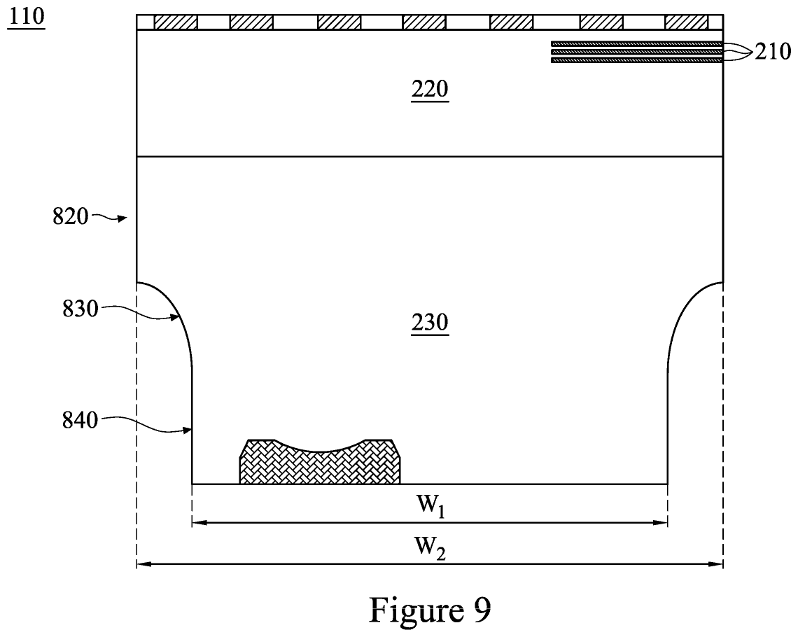

As shown in FIG. 4B, once the first bonding layer 410 has been formed, first openings 420 in the first dielectric material of the first bonding layer 410 are formed to expose conductive portions (not shown) of the underlying layers in the first active portion 220 of the COUPE die 110 in preparation to form first bond pads 440 (shown in FIG. 9D) within first bonding layer 410. Once the first openings 420 have been formed within the first dielectric material, the first openings 420 may be filled with a seed layer (not shown) and a first plate metal 430 (see FIG. 4C) to form the first bond pads within the first bonding layer 410. The seed layer may be blanket deposited over top surfaces of the first dielectric material and the exposed conductive portions (not shown) of the underlying layers in the first active portion 220 of the COUPE die 110 and sidewalls of the first openings 420. The seed layer may comprise a copper layer. The seed layer may be deposited using processes such as sputtering, evaporation, or plasma-enhanced chemical vapor deposition (PECVD), or the like, depending upon the desired materials.

As shown in FIG. 4C, first plate metal 430 may be deposited over the seed layer (not shown) and first dielectric material in the first bonding layer 410 through a plating process such as electroplating or electro-less plating. The first plate metal 430 may comprise copper, a copper alloy, or the like. The first plate metal 430 may be a fill material. A barrier layer (not separately illustrated) may be blanket deposited over top surfaces of the first dielectric material in the first bonding layer 410 and sidewalls of the first openings 420 before the seed layer. The barrier layer may comprise titanium, titanium nitride, tantalum, tantalum nitride, or the like.

As shown in FIG. 4D, following the filling of the first openings 420 with the first plate metal 430, a planarization process, such as a chemical mechanical polishing (CMP), is performed to remove excess portions of the seed layer and the first plate metal 430, forming the first bond pads 440 within the first bonding layer 410. In some embodiments a bond pad via (not separately illustrated) may also be utilized to connect the first bond pads 440 with underlying conductive portions of the COUPE die 110 and, through the underlying conductive portions, connect the first bond pads 440 with underlying metallization layers within the first active portion 220 of the COUPE die 110.

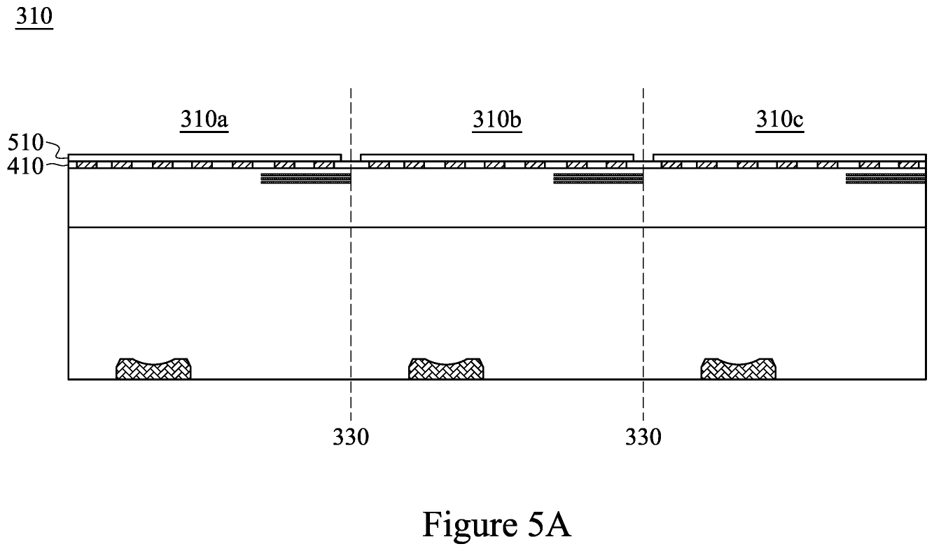

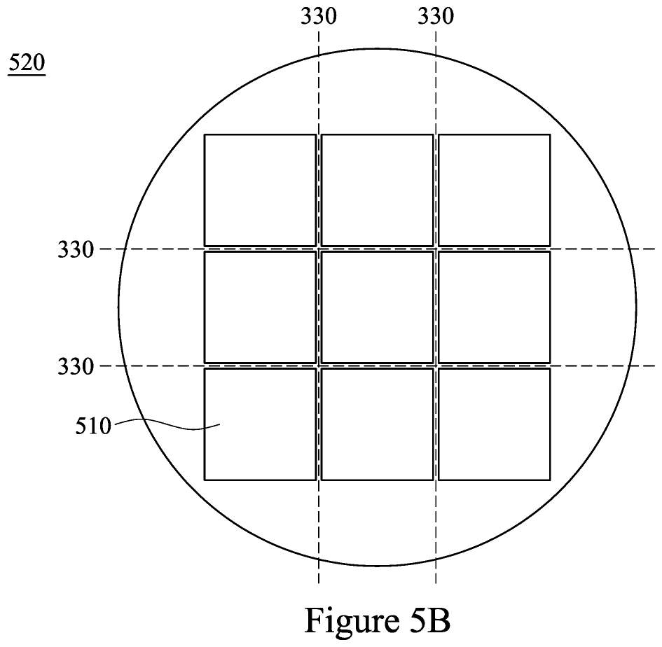

FIGS. 5A-7 illustrate a multi-step singulation process that may be used in order to singulate the individual COUPE dies 110 along scribe lines 330 in preparation for bonding.

In an embodiment, and as illustrated in FIGS. 5A (side view) and 5B (overhead view of the COUPE die regions on a circular wafer 520), the singulation process is initiated by applying a first patterned mask 510 to the COUPE die regions 310 with openings aligned to the scribe lines 330. In some embodiments the openings in the first patterned mask 510 may be between 2 μm and 200 μm.

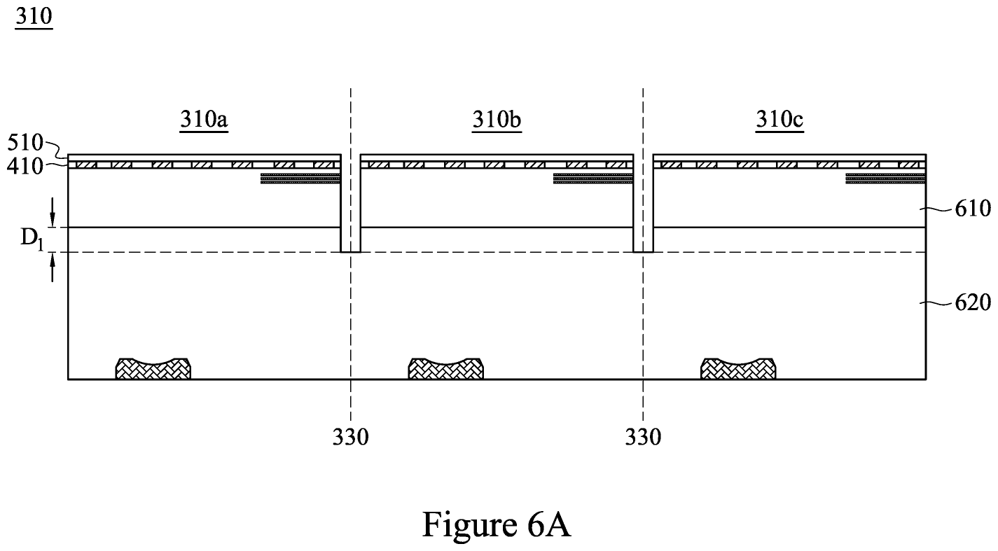

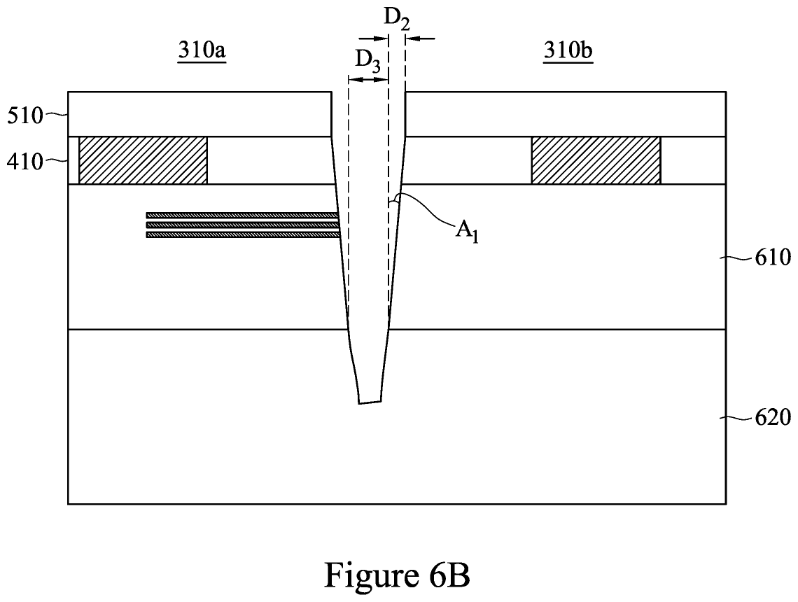

As shown in FIG. 6A, a dry etching process is used to create openings between the first active portion 610 of the individual COUPE die regions 310, and at least partially, but not fully, into the support substrate region 620. In some embodiments, the partial etch depth into the support substrate region 620 may be between 20 μm and 200 μm.

In some embodiments, the dry etching process results in a substantially straight profile. In this context, as shown in FIG. 6B (showing an exaggerated blown-up portion of FIG. 6A), substantially straight means a sidewall profile angle A₁ at less than or equal to about 10 degrees from perpendicular to the major plane of the top of the COUPE die regions 310, and less than about a 100 nm difference in distance D₂ between the sidewall at the top of the active region portion etch and the sidewall at the interface of the first active portion 610 and support substrate region 620. Additionally, the dry etching process results in a trench width D₃ between 2 μm and 200 μm at the interface between the first active portion 610 and support substrate region 620 of the individual COUPE die regions 310.

In some embodiments the etching process may be performed in multiple steps and may utilize a plasma dry etch process and/or a reactive ion etch (RIE). For example, a first reactive ion etch using reactive gases such as CF₄, CAF₈, CHF₃, or CH₃F may be performed to preferentially etch through the dielectric portions of the first bonding layer 410 and the first active portion 610 of the COUPE dies. In some cases, the depth of the trench formed by the first dry etch may be between 3 μm and 30 μm. A second reactive ion etch may then be performed using gases such as SF₆ or NF₃ to preferentially etch between 20 μm and 200 μm into the support substrate. The depth of the etch may be controlled by varying the timing of the etching process, among other process parameters. In some embodiments a third etch may be performed where the third etch is a wet etch to cure any surface defects in the COUPE die resulting from the dry etching process.

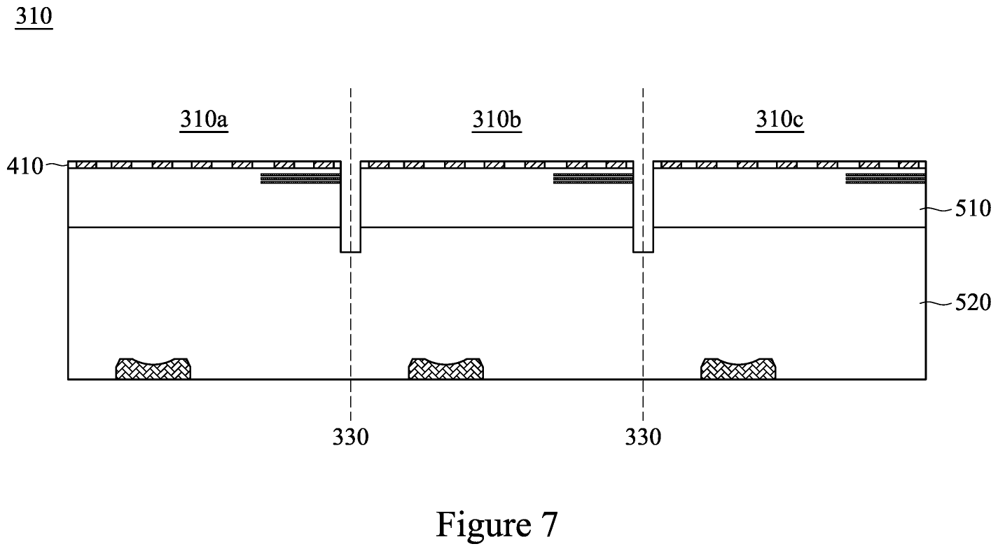

As shown in FIG. 7, the first patterned mask 510 (not shown here) is removed from the COUPE die regions 310. The first patterned mask 510 may be removed by an acceptable ashing or stripping process, such as using an oxygen plasma or the like.

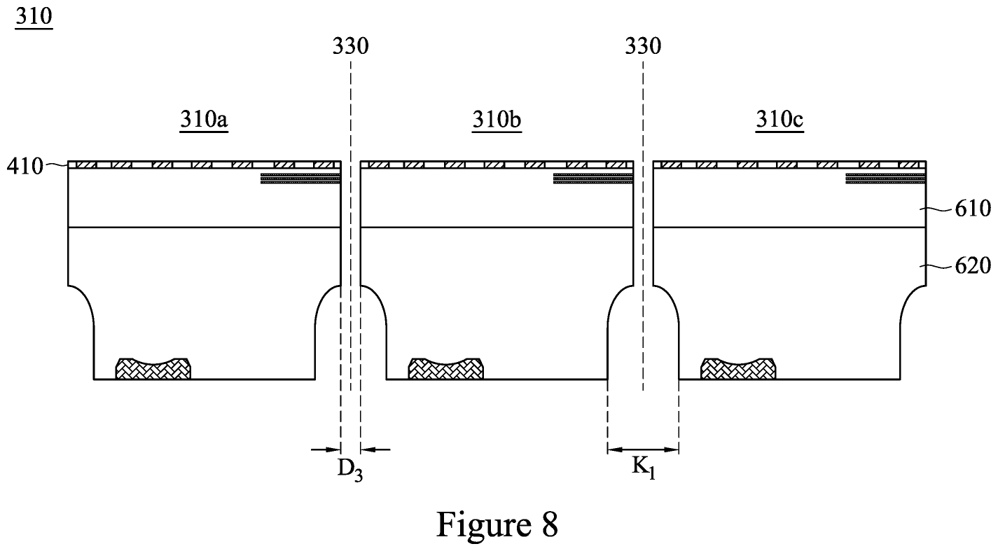

In some embodiments, after the partial etching process, the COUPE die wafer 520 (shown in FIG. 5B) is cleaned and flipped over to complete the multi-step singulation process. As shown in FIG. 8, the COUPE die regions 310 are fully singulated, by sawing along scribe line 330, e.g., between the first COUPE die region 310a and the second COUPE die region 310b, and between the second COUPE die region 310b and the third COUPE die region 310c. The sawing penetrates only the support substrate region 620 of the COUPE dies formed on the wafer 520 with sufficient depth to overlap the trench formed during the dry etching process. In some embodiments the saw depth may be between 80 μm and 650 μm, depending on the size of the support substrate and manufacturing/process requirements. The sawing fully singulates each of the COUPE die regions from adjacent COUPE die regions, and results in singulated COUPE dies 110 (as shown in FIG. 2). In some embodiments the width of the saw kerf (K₁) is 10 μm and 200 μm. However, the saw kerf width K₁ should be wider than the width D₃ of the dry etch trench D₃ (shown in FIG. 6B).

In some embodiments, as shown in FIG. 9, the saw blade has a rounded profile such that sawing along scribe lines 330 (as shown in FIG. 8) result in a singulated COUPE die 110 with a first support substrate 230 having a top sidewall portion 920 that is substantially straight closest to the first active portion 220 (as a result of the etch process described above with reference to FIGS. 6A and 6B), a middle sidewall portion 930 that is rounded and concave, and a bottom sidewall portion 940 that is substantially straight. The first support substrate 230 at the top sidewall portion 920 has a larger first width W₁ than the second width W₂ of the first support substrate 230 at the bottom sidewall portion 940. In some embodiments, other saw blade profiles are envisioned, such as stepped, angled, trapezoidal (having a horizontal and a vertical portion with an angled portion between), or triangular.

By performing a multi-step singulation process as described above, the sidewalls of the first active portion 220 of the singulated COUPE die 110 are smoother than the sawed-through portions of the first support substrate 230. In some embodiments the roughness of the dry etched sidewalls of the first active portion 220 of the singulated COUPE die 110 is less than 10 nm and results in an optical transmission rate at the boundary of the first coupling waveguides 210 of greater than or equal to 99%. In contrast, singulating the COUPE dies 110 using only a saw can result in sidewall roughness greater than 100 nm and optical transmission rates of less than 90%. Accordingly, there is lower optical interference at the boundary of the active portion sidewall, and specifically at the boundary of the first coupling waveguides 210 when transferring optical energy into or out of the COUPE die.

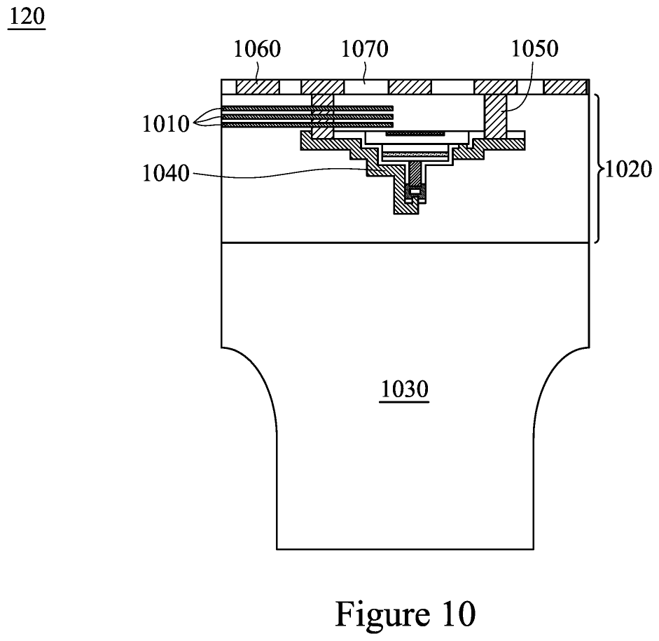

FIG. 10 illustrates an exemplary laser die 120 in accordance with some embodiments. A laser die 120 may comprise a second active portion 1250 on a second support substrate 1030. In some embodiments the second active portion 1250 of the laser die 120 comprises a laser diode 1040. Laser diode 1040 transforms electrical energy, delivered through electrical interconnects 1050, into light energy to one or more of the second coupling waveguides 1010. The laser die 120 additionally includes a second bonding layer comprising second copper bonding pads 1060 and a second dielectric material 1070.

In some embodiments, the second coupling waveguides 1010 may be comprised of silicon nitride. The second coupling waveguides 1010 may be multi-layer, multi-line, or trench style waveguides. For example, in the embodiment shown in FIG. 10, three-multi-layer waveguides are shown. The second coupling waveguides 1010 of the laser die are designed to align at a same horizontal and vertical alignment to the first coupling waveguides 210 of the COUPE die 110 to couple light energy between the laser die 120 and the COUPE die 110. In an embodiment the second coupling waveguides 1010 may be patterned using, e.g., one or more photolithographic masking and etching processes. However, any suitable method of patterning the material for the second coupling waveguides 1010 may be utilized. For example, implantation processes, additional deposition and patterning processes for different materials, combinations of all of these processes, or the like, and can be utilized, and all such combinations are fully intended to be included within the scope of the embodiments.

In an embodiment the second support substrate 1030 may be a material, such as silicon, and may be attached using, e.g., an adhesive (not separately illustrated in FIG. 10). However, in other embodiments the second support substrate 1030 may be bonded to the second active portion 1250 of the laser die 120 using, e.g., a bonding process. Any suitable method of attaching the second support substrate 1030 may be used. As with the first active portions 220 of the COUPE die 110, in some embodiments, second active portion 1250 of laser die 120 could be formed on a bulk substrate that also serves as the support substrate—in which case the above-described separate bonding process would not be necessary.

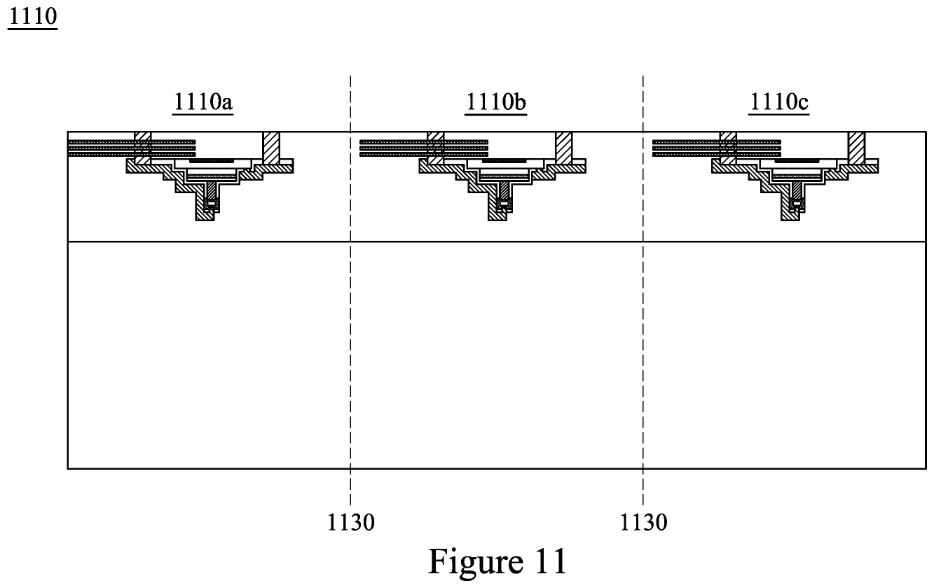

As shown in FIG. 11, in some embodiments, the laser die 120 may be fabricated as part of a larger wafer or panel form fabrication process having multiple die regions such as laser die regions 1110a, 1110b, and 1110c (collectively 1110). Similar to as shown in FIG. 3B, in relation to the COUPE die 110, a circular wafer shape or panel fabrication method may be utilized to fabricate a number of laser dies 120 on a single wafer or panel. The number of laser die regions 1110 that may be included on a single wafer or panel is limited only by physical size of the wafer/panel and the to be fabricated laser dies, and design constraints.

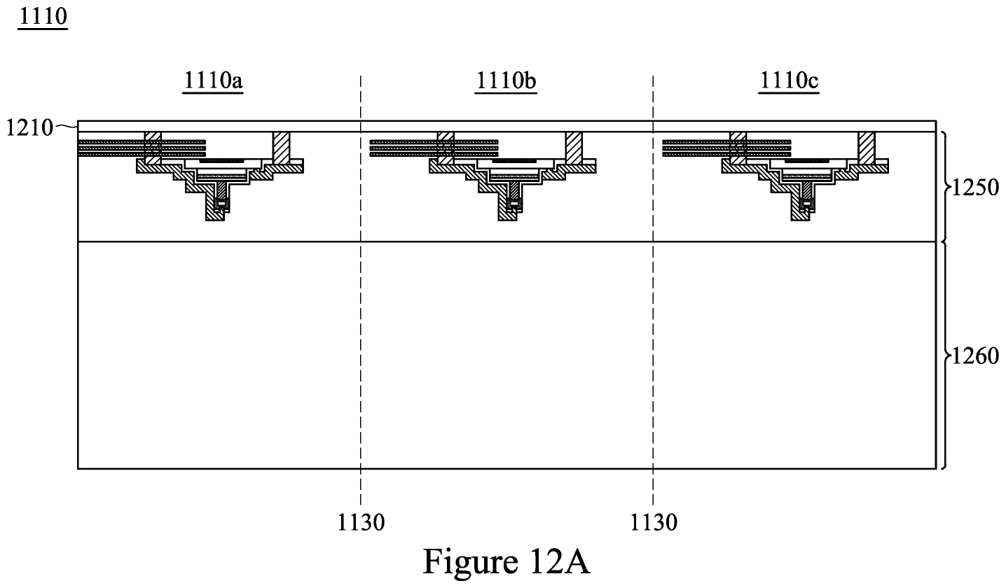

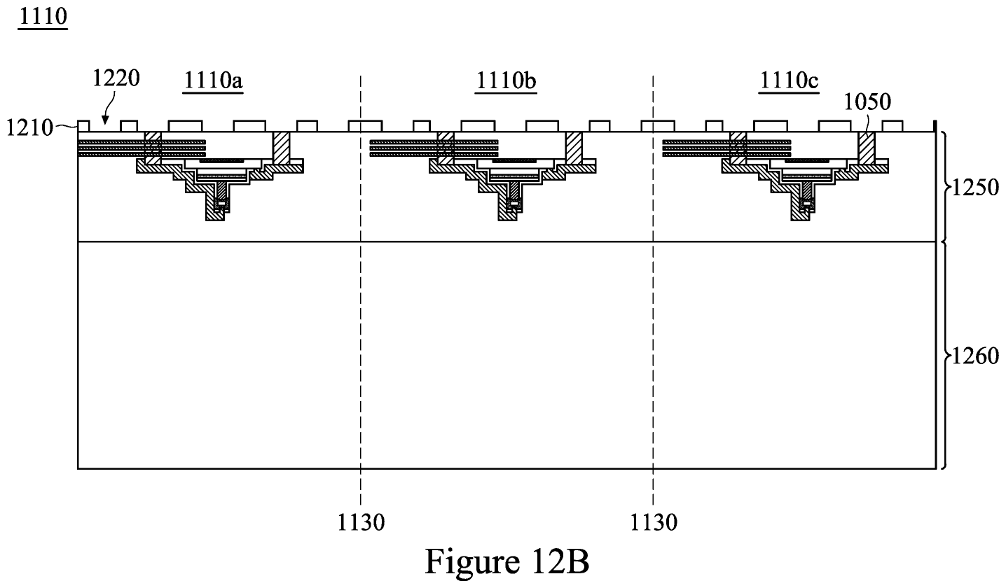

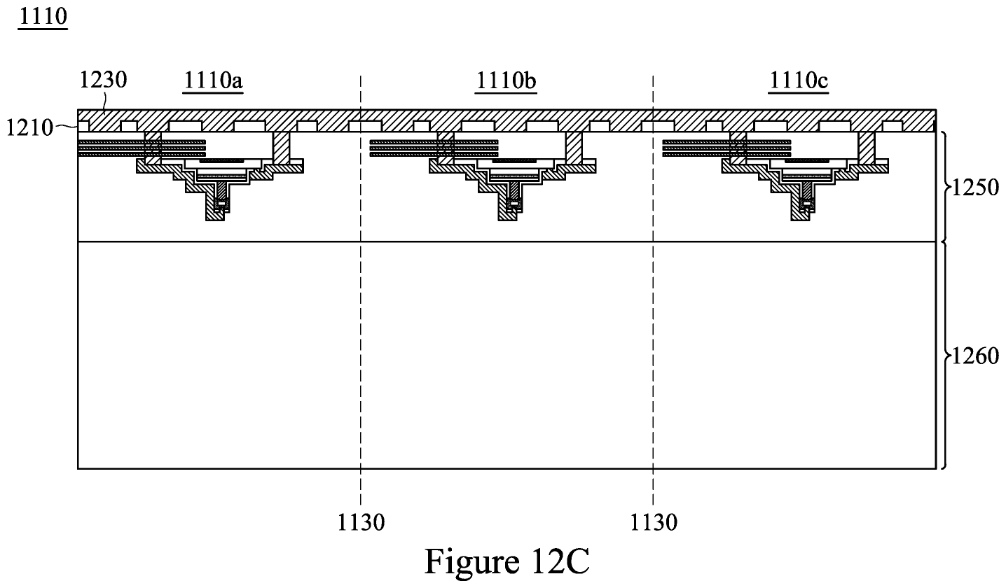

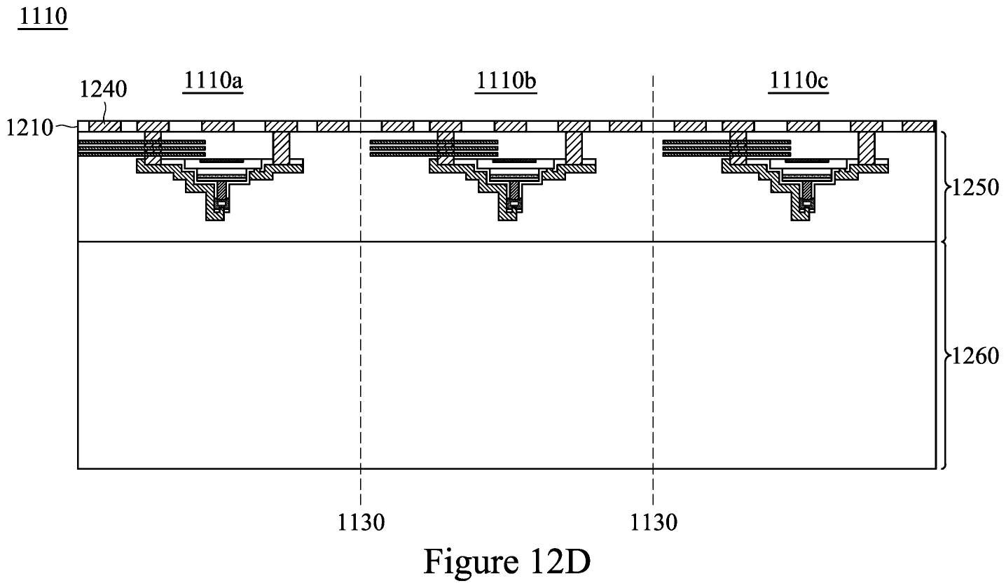

FIGS. 12A-12D show an exemplary embodiment for the preparation of the singulated laser die 120 for bonding within the first integrated package 100.

In accordance with some embodiments, as shown in FIG. 12A, a second bonding layer 1210 is formed of a second dielectric material such as silicon oxide, silicon nitride, or the like. The second dielectric material may be deposited using any suitable method, such as CVD, high-density plasma chemical vapor deposition (HDPCVD), PVD, atomic layer deposition (ALD), or the like. However, any suitable materials and deposition processes may be utilized. The second bonding layer 1210 may later be used for a dielectric-to-dielectric and metal-to-metal bonding between the singulated laser die 120 and the interposer 130.

As shown in FIG. 12B, once the second bonding layer 1210 has been formed, second openings 1220 in the second bonding layer 1210 are formed to expose conductive portions (not shown) and electrical interconnects 1050 of the underlying layers in the second active portion 1250 of the laser die 120 (see FIG. 10) in preparation to form second bond pads 1240 (FIG. 12D) within the second bonding layer 1210. Once the second openings 1220 have been formed within the second dielectric material, the second openings 1220 may be filled with a seed layer (not shown) and a second plate metal 1230 to form the second bond pads 1240 within the second bonding layer 1210. The seed layer may be blanket deposited over top surfaces of the second dielectric material and the exposed conductive portions (not shown) and electrical interconnects 1050 of the underlying layers in the second active portion 1250 of the singulated laser die 120 and sidewalls of the second openings 1220. The seed layer may comprise a copper layer. The seed layer may be deposited using processes such as sputtering, evaporation, or plasma-enhanced chemical vapor deposition (PECVD), or the like, depending upon the desired materials.

As shown in FIG. 12C, second plate metal 1230 may be deposited over the seed layer (not shown) and second dielectric material in the second bonding layer 1210 through a plating process such as electroplating or electro-less plating. The second plate metal 1230 may comprise copper, a copper alloy, or the like. The second plate metal 1230 may be a fill material. A barrier layer (not separately illustrated) may be blanket deposited over top surfaces of the second dielectric material in the second bonding layer 1210 and sidewalls of the second openings 1220 before the seed layer. The barrier layer may comprise titanium, titanium nitride, tantalum, tantalum nitride, or the like.

As shown in FIG. 12D, following the filling of the second openings 1220 with the second plate metal 1230, a planarization process, such as a chemical mechanical polishing (CMP), is performed to remove excess portions of the seed layer and the second plate metal 1230, forming the second bond pads 1240 within the second bonding layer 1210.

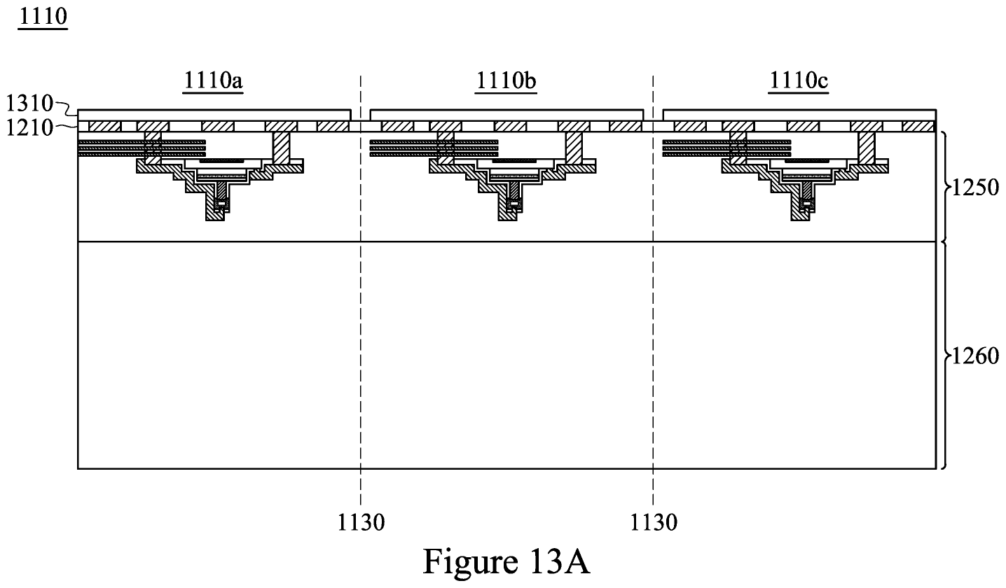

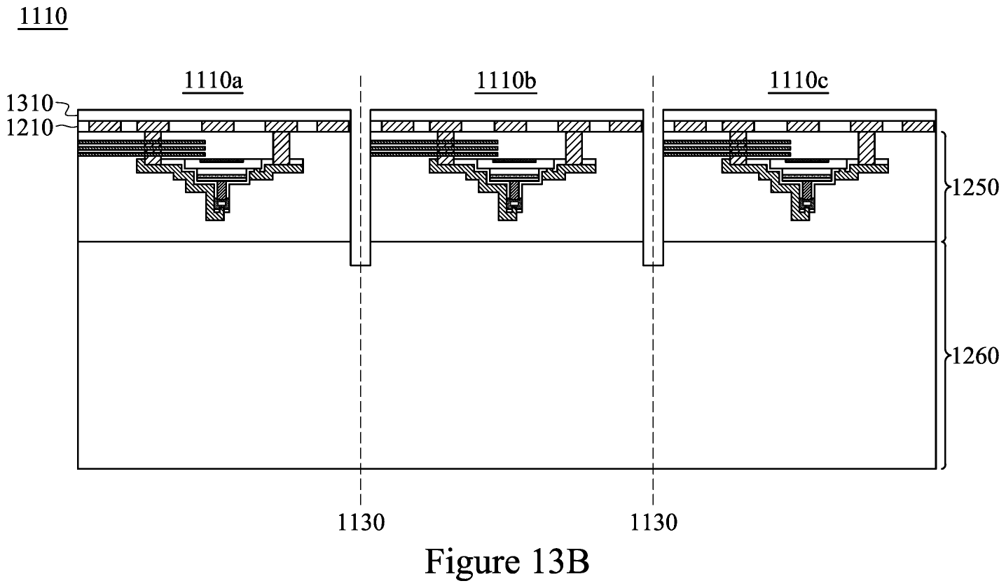

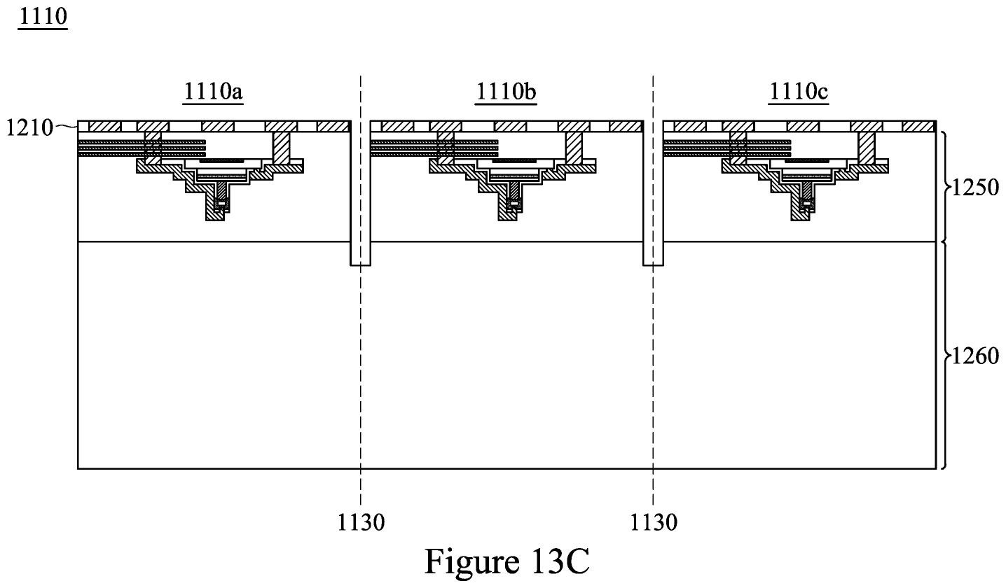

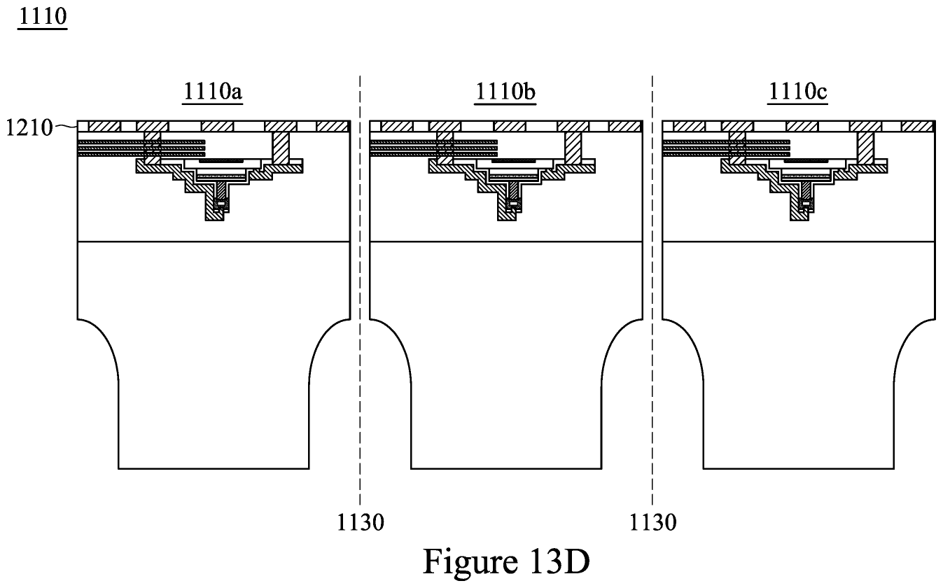

FIGS. 13A-D illustrate a multi-step singulation process that may be used in order to singulate the individual laser dies 120 along scribe lines 1130 in preparation for bonding.

In an embodiment, and as illustrated in FIG. 13A (side view), the singulation process is initiated by applying a second patterned mask 1310 to the laser die regions 1110 with openings aligned to the scribe lines 1130. In some embodiments the openings in the second patterned mask 1310 may be between 2 μm and 200 μm.

As shown in FIG. 13B, a dry etching process is used to create openings between the second active portion 1250 of the individual laser die regions 1110, and at least partially, but not fully, into the second support substrate 1260. In some embodiments, the partial etch depth into the second support substrate 1260 may be between 20 μm and 200 μm.

In some embodiments, the dry etching process results in a substantially straight profile. In this context, and as shown in FIG. 6B in relation to the COUPE die 110, substantially straight means a sidewall profile angle A₁ (as shown in relation to the COUPE die 110 in FIG. 6B) at less than or equal to about 10 degrees from perpendicular to the major plane of the top of the laser die regions 1110, and less than about a 100 nm difference in distance D₂ (as shown in relation to the COUPE die 110 in FIG. 6B) between the sidewall at the top of the active region portion etch and the sidewall at the interface of the second active portion 1250 and second support substrate 1260. Additionally, the dry etching process results in a trench width D₃ between 2 μm and 200 μm at the interface between the active portion 610 and support substrate region 620 of the individual COUPE die regions 310.

In some embodiments the etching process may be performed in multiple steps and may utilize a plasma dry etch process and/or a reactive ion etch (RIE). For example, a fourth reactive ion etch using reactive gases such as CF₄, C₄F₈, CHF₃, or CH₃F may be performed to preferentially etch through the dielectric portions of the second bonding layer 1210 and the second active portion 1250 of the laser dies. In some cases, the depth of the trench formed by the first dry etch may be between 3 μm and 30 μm. A fifth reactive ion etch may then be performed using gases such as SF₆ or NF₃ to preferentially etch between 20 μm and 200 μm into the second support substrate 1260. The depth of the etch may be controlled by varying the timing of the etching process, among other process parameters. In some embodiments a sixth etch may be performed where the third etch is a wet etch to cure any surface defects in the laser die resulting from the dry etching process.

As shown in FIG. 13C, the second patterned mask 1310 (not shown here) is removed from the laser die regions 1110. The second patterned mask 1310 may be removed by an acceptable ashing or stripping process, such as using an oxygen plasma or the like.

In some embodiments, after the partial etching process, the laser die wafer (not shown) is cleaned and flipped over to complete the multi-step singulation process. As shown in FIG. 13D, the laser die regions 1110 are fully singulated, by sawing along scribe line 1130, e.g., between the first laser die region 1110a and the second laser die region 1110b, and between the second laser die region 1110b and the third laser die region 1110c. The sawing penetrates only the second support substrate 1260 of the laser dies formed on the wafer with sufficient depth to overlap the trench formed during the dry etching process. In some embodiments the saw depth may be between 80 μm and 650 μm, depending on the size of the support substrate and manufacturing/process requirements. The sawing fully singulates each of the laser die regions from adjacent laser die regions, and results in singulated laser dies 120 (as shown in FIG. 10). In some embodiments the width of the saw kerf is 10 μm and 200 μm. However, the saw kerf width K₁ should be wider than the width D₃ of the dry etch trench D₃ (shown in FIG. 8 in relation to the COUPE die).

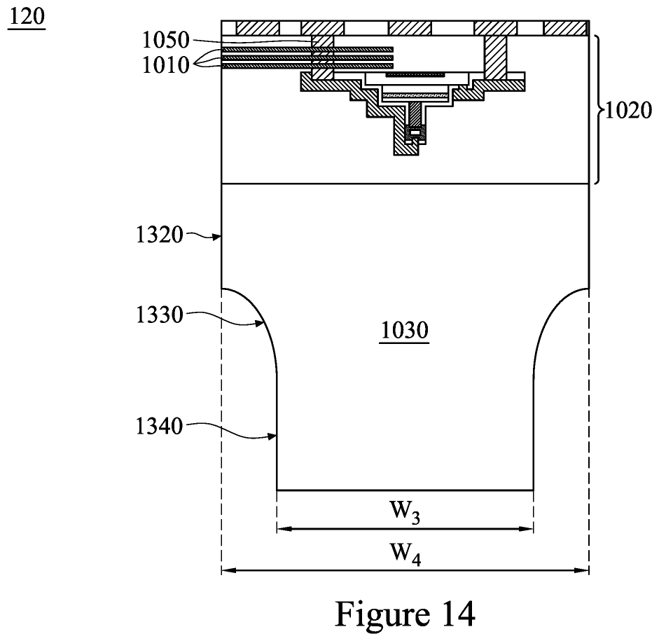

In some embodiments, as shown in FIG. 14, the saw blade has a rounded profile such that sawing along scribe lines 1130 (as shown in FIG. 13D) result in a singulated laser die 120 with a second support substrate 1030 having a top sidewall portion 1320 that is substantially straight closest to the second active portion 1250, a middle sidewall portion 1330 that is rounded and concave, and a bottom sidewall portion 1340 that is substantially straight. The second support substrate 1030 at the top sidewall portion 1320 has a larger third width W₃ than the fourth width W₄ of the second support substrate 1030 at the bottom sidewall portion 1340. In some embodiments, other saw blade profiles are envisioned, such as stepped, angled, trapezoidal (having a horizontal and a vertical portion with an angled portion between), or triangular.

By performing a multi-step singulation process as described above, the sidewalls of the second active portion 1250 of the singulated laser die 120 are smoother than the sawed-through portions of the second support substrate 1030. Accordingly, there is lower optical interference at the boundary of the active portion sidewall, and specifically at the boundary of the second coupling waveguides 1010 when transferring optical energy into or out of the laser die.

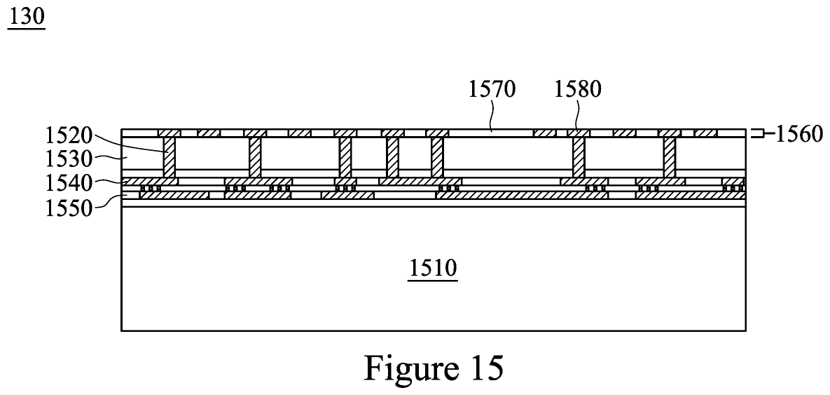

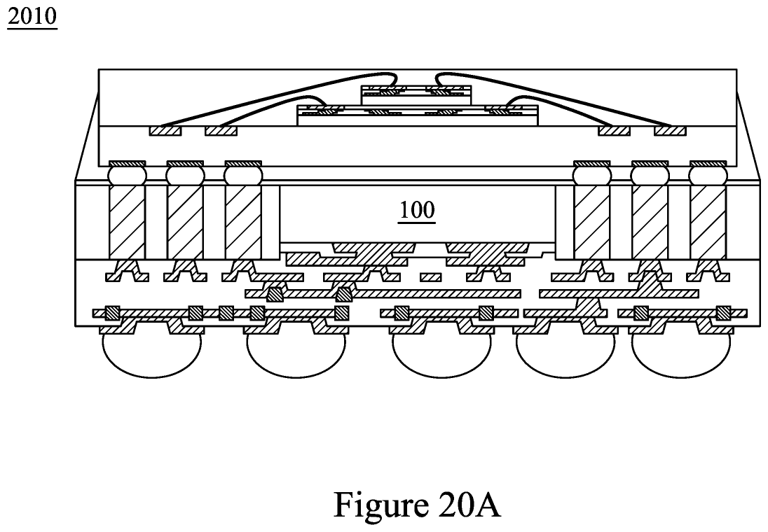

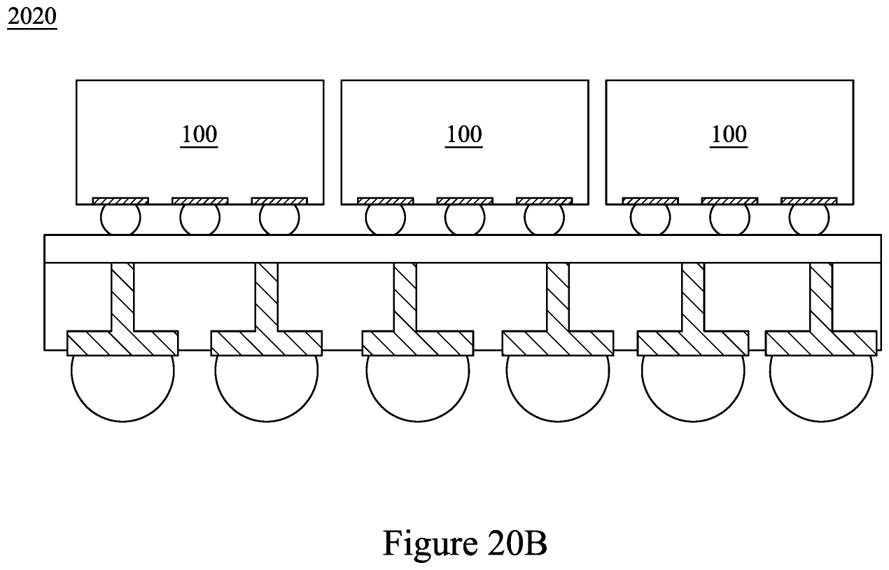

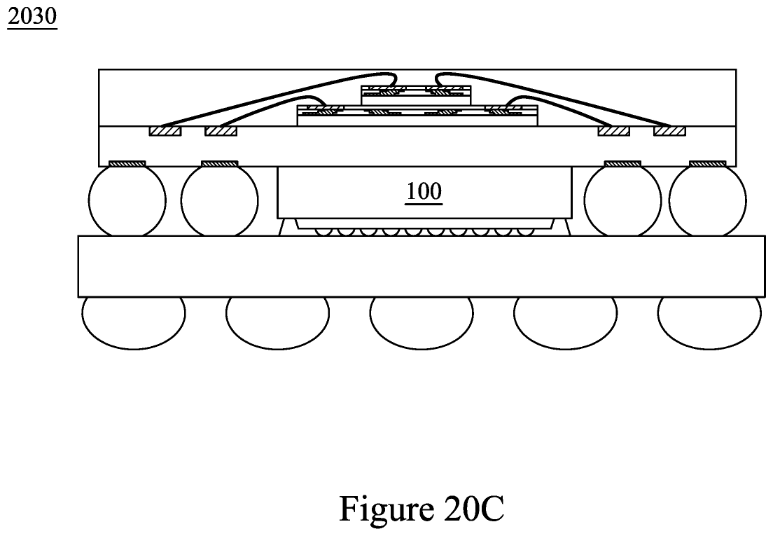

FIG. 15 shows an exemplary embodiment of the interposer 130. The interposer 130 metallization layers are formed on a third substrate 1510 in order to electrically connect the first active portion 220 of the singulated COUPE die 110 and second active portion 1020 of the singulated laser die 120 to control circuitry, to each other, and to subsequently attached devices (not illustrated in FIG. 15 but illustrated and described further below with respect to FIGS. 20A-20C).

In an embodiment, the third substrate 1510 may be a material that can be used not only for structural support but also may be used as a seed material for epitaxially growing overlying materials and may be, for example, a 2-inch or 4-inch wafer of material, although any suitable size and material may be utilized. In an embodiment the third substrate 1510 may be a semiconductor material used for structural support during subsequent processing, and may be, e.g., a silicon wafer, a silicon germanium wafer, a silicon-on-insulator wafer, or the like. The third substrate 1510 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

Optionally, active devices (not shown here) may be added to the third substrate 1510. The active devices comprise a wide variety of active devices and passive devices such as capacitors, resistors, inductors and the like that may be used to generate the desired structural and functional requirements of the design for the third substrate 1510. The active devices may be formed using any suitable methods either within or else on the third substrate 1510.

In an embodiment the metallization layers are formed of alternating layers of dielectric material 1550 (e.g., low-k dielectric materials, extremely low-k dielectric material, ultra low-k dielectric materials, combinations of these, or the like) and conductive material 1540 and may be formed through any suitable processes (such as deposition, damascene, dual damascene, etc.). However, any suitable materials and processes may be utilized. In particular embodiments there may be multiple layers of metallization used to interconnect the various optical components, but the precise number of metallization layers is dependent upon the design of the interposer 130 and the first integrated package 100.

In some embodiments, the interposer 130 may additionally include a core substrate and/or dielectric layers 1530, and bonding vias 1520 electrically connecting the conductive material 1540 in the metallization layers to the third bonding pads 1580 in a third bonding layer 1560. The third bonding layer 1560 additionally includes a third dielectric material 1570. The third bonding layer may be formed using a damascene, dual damascene, etc., process as described above in relation to FIGS. 4A-4D of the singulated COUPE die 110 or FIGS. 12A-D of the singulated laser die 120.

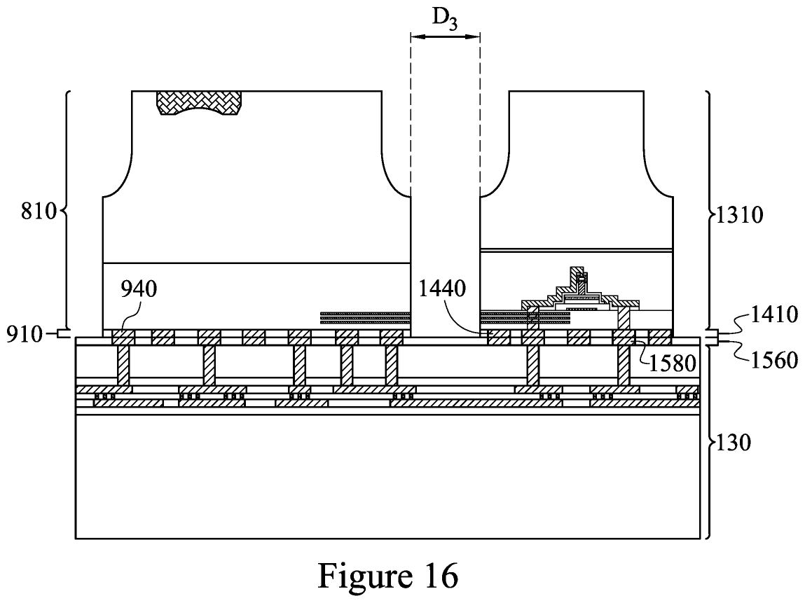

FIG. 16 illustrates the bonding of a singulated COUPE die 110 and a singulated laser dies 120 to the interposer 130. In a particular embodiment the first bonding layer 910 of the singulated COUPE die 110 and the second bonding layer 1410 of the singulated laser die 120 may each be bonded to the third bonding layer 1560 of the interposer 130 using a dielectric-to-dielectric and metal-to-metal bonding process. However, any other suitable bonding process may also be utilized.

In a particular embodiment which utilizes a dielectric-to-dielectric and metal-to-metal bonding process, the process may be initiated by activating the surfaces of the singulated COUPE die 110, the surfaces of the first bonding layer 910, the surfaces of the singulated laser die 120, the surfaces of the second bonding layer 1410, the surfaces of the interposer, and the surfaces of the third bonding layer 1560. Activating the top surfaces of the bonding layers, the singulated COUPE die 110, the singulated laser die 120, and the interposer 130 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the singulated COUPE die 110 and the singulated laser die 120 to the interposer 130.

After the activation process the interposer 130, the singulated COUPE die 110, and the singulated laser die 120 may be cleaned using, e.g., a chemical rinse, and then the singulated COUPE die 110 and the singulated laser die 120 are aligned and placed into physical contact with the interposer 130. In some embodiments, the singulated COUPE die 110 and the singulated laser die 120 may be placed on the interposer 130 at a distance D₃ between about 5 μm to about 100 μm apart.

The interposer 130, the singulated COUPE die 110, the singulated laser die 120 are then subjected to thermal treatment and contact pressure to bond the singulated COUPE die 110 and the singulated laser die 120 to the interposer 130. For example, the interposer 130, the singulated COUPE die 110, and the singulated laser die 120 may be subjected to a pressure of about 200 kPa or less, and a temperature between about 25° C. and about 250° C. to fuse the singulated COUPE die 110 and the singulated laser die 120 with the interposer 130. The interposer 130, the singulated COUPE die 110, and the singulated laser die 120 may then be subjected to a temperature at or above the eutectic point for material of the first bond pads 440, second bond pad 1240, and the third bond pads 1580, e.g., between about 150° C. and about 650° C., to fuse the metal. In this manner, the singulated COUPE die 110 and the singulated laser die 120 forms a dielectric-to-dielectric and metal-to-metal bonded device with the interposer 130. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

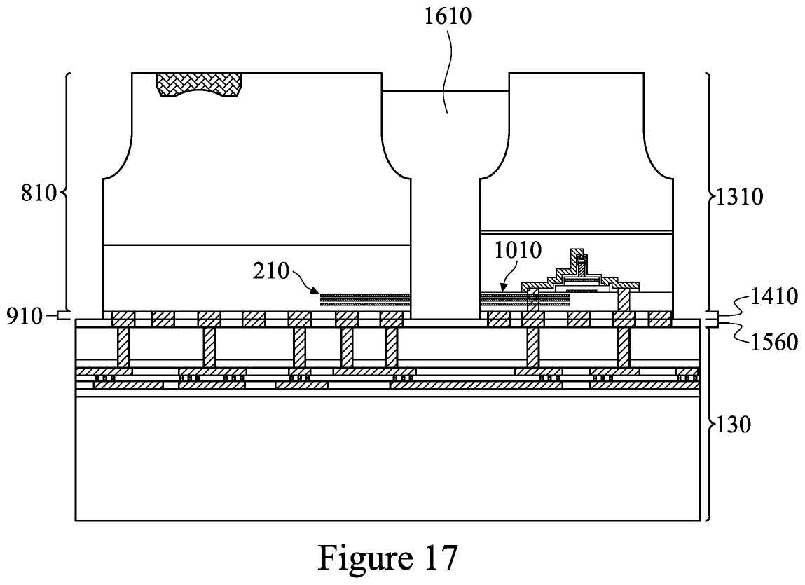

FIG. 17 shows an embodiment in which an optical glue 1610 fill is applied to the cavity between the singulated COUPE die 110 and the singulated laser die 120. Due to the shape of the sidewalls of the singulated COUPE die 110 and the singulated laser die 120 from the multi-step singulation process described above, the space between the singulated COUPE die 110 and the singulated laser die 120 at the top (furthest from the interposer 130) is larger than the space between the singulated COUPE die 110 and the singulated laser die 120 at the bottom (closest to the interposer 130). Accordingly, the optical glue more easily flows from top to bottom and completely fills the cavity between the singulated COUPE die 110 and the singulated laser die 120. Additionally, due to the multi-step singulation process described above, the roughness of the dry etched sidewalls of the singulated COUPE die 110 and the laser die 120 are less than 10 nm. Accordingly, optical transmission rate at the boundary of the first coupling waveguides 210 with the optical glue, and at the boundary of the second coupling waveguides 1010 and the optical glue, is greater than or equal to 99%. In contrast, optical transmission rates at boundaries formed by sawing can result in a sidewall roughness greater than 100 nm, and associated optical transmission rates of less than 90%. Accordingly, the disclosed embodiments and processes result in fewer manufacturing defects and reduced optical transmission losses between the optically coupled dies.

Due to the preparation of the bonding layers of the singulated COUPE die 110, the singulated laser die 120, and the interposer 130, and specifically due to the CMP finishing of each of the associated bonding layers described above, the surfaces of the singulated COUPE die 110, the singulated laser die 120, and the interposer 130 achieve a high level of coplanarity. As a result, when compared to conventional methods utilizing micro-bump joint between dies and an interposer, vertical shift between the alignment of the singulated COUPE die 110 and the singulated laser die 120 after placement from a reflow bonding process is virtually eliminated, or at least substantially reduced.

The dielectric-to-dielectric and metal-to-metal bond has the added benefit of resulting in harder rigidity of the individual components due at least in part to the stronger silicon oxide bond. The dielectric-to-dielectric and metal-to-metal bond additionally results in reduced vertical shift when compared to conventional micro-bump joints. Conventional micro-bump joints exhibit a 1 μm to 3 μm horizontal shift during reflow. In comparison the dielectric-to-dielectric and metal-to-metal bond limits the horizontal shift to between 0.2 μm to 0.8 μm. All these benefits result in improved optical alignment between the first coupling waveguides 210 of the singulated COUPE die 110 and second coupling waveguides 1010 of the singulated laser die 120. This results in lower optical loss, fewer manufacturing defects, larger allowable design tolerances, and smaller sized manufacturing capabilities relative to conventional bonding approached such as micro-bump joints.

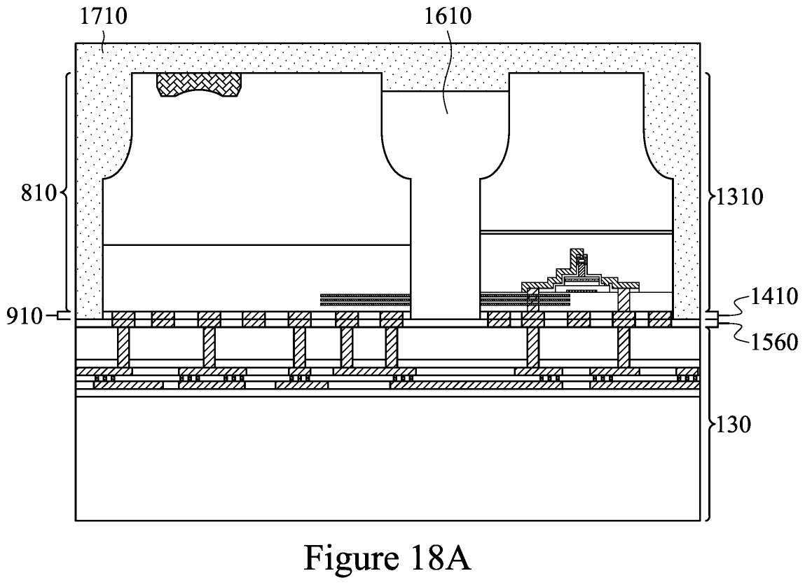

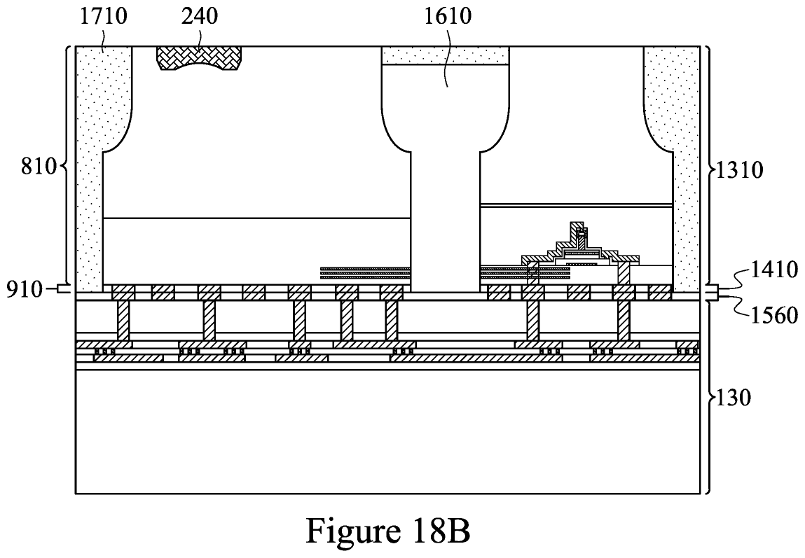

In some embodiments, as shown in FIG. 18A, a fill is performed by forming encapsulant 1710 on and around the various components. In some embodiments the encapsulant 1710 covers at least the top of the interposer 130 and surrounds the singulated COUPE die 110 and the singulated laser die 120. In some embodiments the top of the optical glue 1610 is also covered by the encapsulant 1710. The encapsulant 1710 may be formed of a molding compound, epoxy, or the like, and may be applied by compression molding, transfer molding, or the like. The encapsulant 1710 may be applied in liquid or semi-liquid form and then subsequently cured. The encapsulant 1710 may be formed over the interposer 130 such that the singulated COUPE die 110, the singulated laser die 120, and the optical glue 1610 are buried or covered.

In FIG. 18B, a planarization process may be performed, in some embodiments, on the encapsulant 1710 to expose the coupling lens 240 of the singulated COUPE die 110. In some instances, the topmost surfaces of the singulated COUPE die 110, the singulated laser die 120, and/or the optical glue 1610 may be exposed as well. The topmost surface of the first integrated package 100 is substantially level (e.g., planar) after the planarization process within process variations. The planarization process may be, for example, a chemical-mechanical polish (CMP), a grinding process, or the like. In some embodiments, the planarization may be omitted, for example, if the coupling lens 240 of the singulated COUPE die 110 is already exposed. Other processes may be used to achieve a similar result.

In instances where the coupling lens 240 of the singulated COUPE die 110 is recessed below the topmost surface of the singulated COUPE die 110, further etching, grinding, and/or patterning may be performed on the encapsulant 1710 to expose the coupling lens 240 of the singulated COUPE die 110.

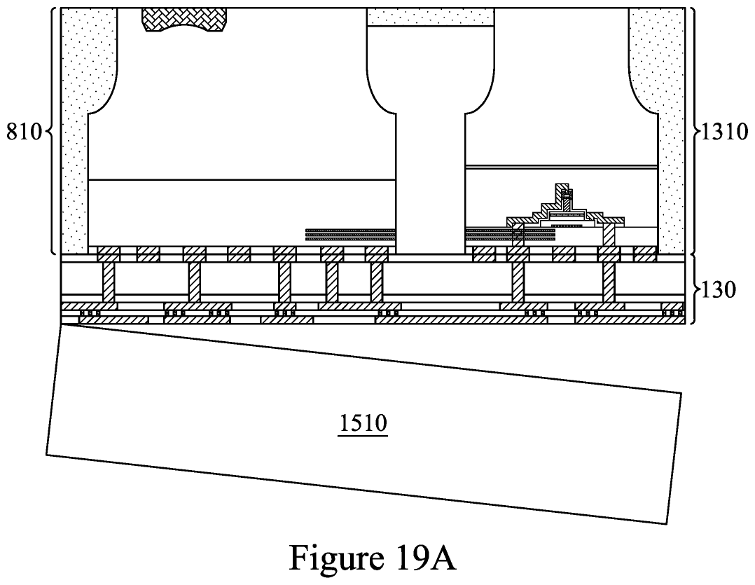

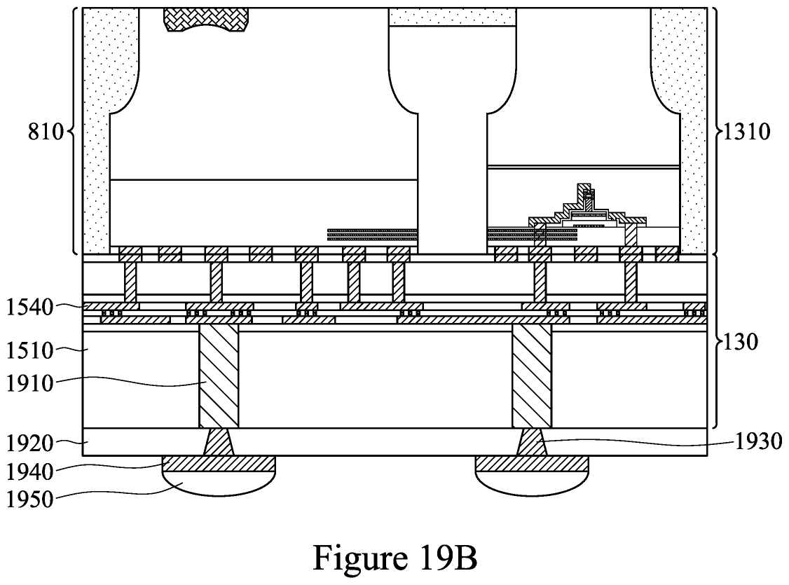

FIG. 19A-B illustrates alternative back-end connection possibilities for the first integrated package 100.

In some embodiments, as shown in FIG. 19A, a substrate de-bonding is performed to detach (or “de-bond”) the third substrate 1510 from the interposer 130. In accordance with some embodiments, the de-bonding includes projecting a light such as a laser light or an UV light on the release layer (not shown) so that the release layer decomposes under the heat of the light and the third substrate 1510 can be removed.

As shown in FIG. 1, a redistributive layer portion 160 may be attached and/or formed on the bottom of the interposer 130. The redistributive layer portion 160 comprises metallization layers 190 and dielectric layers 195 that route signaling and power between the interposer and external components (not shown in FIG. 1) through external connectors 170. In some embodiments, the external connectors 170 may be part of micro-bump joints additionally comprising solder portions 180. Any suitable methods may be used for forming and patterning the redistributive layer portion 160 and external connectors 170.

In other embodiments, such as shown in FIG. 19B, the third substrate 1510 may instead be maintained on the interposer 130, and through silicon vias (TSVs) 1910 formed to connect the conductive material 1540 of the metallization layers of the interposer 130 to external connectors 1940. Additional metallization layers may be added to the bottom of the interposer 130 consisting of further dielectric materials 1920 and metallization materials 1930. Any suitable methods may be used for forming and patterning the through silicon vias (TSVs) 1910, external connectors 1940, and further dielectric materials 1920 and metallization materials 1930.

For example, in a possible embodiment, at any desired point in the manufacturing process, the TSVs 1910 may be formed within the third substrate 1510 in order to provide electrical connectivity from a front side of the third substrate 1510 to a back side of the third substrate 1510. In an embodiment the second TSVs 1910 may be formed by initially forming through silicon via (TSV) openings into the third substrate 1510 prior to forming the alternating layers of dielectric material 1550 and conductive materials 1540, as well as the third bonding layer 1560, as described in relation to FIG. 15 above. The TSV openings may be formed by applying and developing a suitable photoresist, and removing portions of the underlying materials that are exposed to a desired depth. The TSV openings may be formed so as to extend into the third substrate 1510 to a depth greater than the eventual desired height of the third substrate 1510.

Once the TSV openings have been formed within the third substrate 1510, the TSV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used.

Once the liner has been formed along the sidewalls and bottom of the TSV openings, a barrier layer may be formed and the remainder of the TSV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TSV openings. Once the TSV openings have been filled, excess liner, barrier layer, seed layer, and conductive material outside of the TSV openings may be removed through a planarization process such as chemical mechanical polishing (CMP), although any suitable removal process may be used.

Once the TSV openings have been filled, after the formation of the alternating layers of dielectric material 1550 and conductive materials 1540, as well as the formation of the third bonding layer 1560, and after bonding the COUPE die(s) 810 and laser die(s) 1310 to the interposer 130, the third substrate 1510 may be thinned until the TSVs 1910 have been exposed. In an embodiment the third substrate 1510 may be thinned using, e.g., a chemical mechanical polishing process, a grinding process, or the like. Further, once exposed, the TSVs 1910 may be recessed using, e.g., one or more etching processes, such as a wet etch process in order to recess the third substrate 1510 so that the TSVs 1910 extend out of the third substrate 1510.

In an embodiment the second external connectors 1940 may be placed on the third substrate 1510 in electrical connection with the second TSVs 1910 and may be, e.g., a ball grid array (BGA) which comprises a eutectic material such as solder 1950, although any suitable materials may be used. Optionally, an underbump metallization or additional metallization layers (not separately illustrated in FIG. 19B) may be utilized between the third substrate 1510 and the external connectors 1940. In an embodiment in which the external connectors 1940 include are solder bumps 1950, the external connectors 1940 may be formed using a ball drop method, such as a direct ball drop process. In another embodiment, the solder bumps 1950 may be formed by initially forming a layer of tin through any suitable method such as evaporation, electroplating, printing, solder transfer, and then performing a reflow in order to shape the material into the desired bump shape. Once the external connectors 1940 have been formed, a test may be performed to ensure that the structure is suitable for further processing.

Embodiments have been described with respect to a specific context, namely applied to a system on integrated chip (SoIC) package. However, other embodiments may also be applied to other packages, including Chip-on-Wafer-on-Substrate (CoWoS®) packages or integrated fan-out (InFO) packages, as examples. Further, as shown in FIGS. 20A-C, one or more first integrated packages 100 may be further included in overarching packaging. For example, FIG. 20A shows an embodiment where a first integrated packages 100 is included in an InFO package 2010. FIG. 20B shows an embodiment where multiple first integrated packages 100 are included in an CoWoS® package 2020. FIG. 20C shows an embodiment where the first integrated package 100 is included in a flip chip package 2030. Embodiments discussed herein are to provide examples to enable making or using the subject matter of this disclosure, and a person having ordinary skill in the art will readily understand modifications that can be made while remaining within contemplated scopes of different embodiments. Like reference numbers and characters in the figures below refer to like components. Although method embodiments may be discussed as being performed in a particular order, other method embodiments may be performed in any logical order.

By utilizing the methods and processes as described above, vertical misalignment during fabrication between dies sending and receiving optical signals/energy can be virtually eliminated or at least substantially reduced, and horizontal misalignment during fabrication can be greatly reduced. Further, optical losses resulting from medium shifts between dies sending and receiving optical signals/energy can be reduced. Accordingly, utilizing the processes described can result in fewer manufacturing defects, and allow for smaller optical design requirements.

In an embodiment, an integrated package includes: an optical die, where the optical die include photonic integrated circuits (PICs), electronic integrated circuits (EICs), and one or more first coupling waveguides; a laser die, where the laser die includes at least one laser diode, and one or more second coupling waveguides; an interposer, where the optical die is bonded to a first side of the interposer using a metal-to-metal bonding, where the laser die is bonded to the first side of the interposer using a metal-to-metal bonding, and where at least one of the one or more first coupling waveguides is optically aligned with at least one of the one or more second coupling waveguides; and an optical glue filling a gap between the aligned at least one of the one or more first coupling waveguides and the at least one of the one or more second coupling waveguides.

In an embodiment, the integrated package further includes an encapsulant, where the encapsulant covers the interposer and surrounds the optical die, the laser die, and the optical glue.

In an embodiment, the integrated package further includes a redistribution structure on a second side of the interposer opposite the first side, where the redistribution structure includes one or more layers of dielectric and one or more layers of metallization, and where the one or more layers of metallization electrically connect the interposer to a plurality of external connectors.

In an embodiment, the integrated package further includes a silicon substrate attached to a second side of the interposer opposite the first side, where the silicon substrate includes through-silicon vias (TSVs) through the silicon substrate and electrically connecting the interposer to a plurality of external connectors.

In an embodiment, at least two sidewalls of the optical die include a substantially straight first portion closest to the interposer, a substantially straight second portion furthest from the interposer, and a third portion between the first portion and the second portion that is tapered; where the at least two sidewalls are on opposite sides of the optical die, where at least one of the at least two sidewalls intersects with the least one of the one or more first coupling waveguides optically aligned with the at least one of the one or more second coupling waveguides; and where a first width of the optical die between the first portion of the at least two sidewalls is larger than a second width of the optical die between the second portion of the at least two sidewalls.

In an embodiment, the third portion is tapered to form a rounded concave profile in the sidewall of the optical die between the first portion and the second portion of the sidewall.

In an embodiment, the optical die and the laser die are horizontally spaced between about 5 μm and about 100 μm apart on the interposer, and the optical die and laser die are each further bonded to the interposer using a dielectric-to-dielectric bond.

In an embodiment, a method for forming an integrated package includes: forming a first bonding layer, including a first dielectric layer and a first metallization layer, on a first side of an optical die, where the optical die includes photonic integrated circuits (PICs), electronic integrated circuits (EICs), and one or more first coupling waveguides; forming a second bonding layer, including a second dielectric layer and a second metallization layer, on a first side of a laser die, where the laser die includes at least one laser diode and one or more second coupling waveguides; forming a third bonding layer, including a third dielectric layer and a third metallization layer, on a first side of an interposer; aligning the first side of the optical die and the first side of the laser die on the first side of the interposer, where the first bonding layer of the optical die and the second bonding layer of the laser die are in physical contact with the third bonding layer of the interposer, and where at least one of the one or more first coupling waveguides is optically aligned with at least one of the one or more second coupling waveguides; forming a metal-to-metal bond between the first bonding layer and the third bonding layer and between the second bonding layer and the third bonding layer; and filling a void between the optical die and the laser die with an optical glue.

In an embodiment, the method of forming the integrated package further includes, before aligning the first side of the optical die and the first side of the laser die on the first side of the interposer, a multi-step singulation of the optical die including: performing a dry etch from a first direction to partially singulate between at least two optical dies, where the dry etch forms a trench penetrating into the optical die through an active portion of the optical die, and where the dry etch partially penetrates through a first substrate of the optical die attached to the active portion of the optical die; and sawing through an un-etched portion of the first substrate from a second direction, opposite the first direction, using a saw blade, where the saw blade forms a tapered or rounded cutting profile in at least a portion of a cut surface of the first substrate, and where a largest width of a cutting portion of the saw blade is greater than a largest width of the dry etch trench.

In an embodiment, the method of forming the integrated package further includes, before aligning the first side of the optical die and the first side of the laser die on the first side of the interposer, a multi-step singulation of the laser die including: performing a dry etch from a first direction to partially singulate between at least two laser dies, where the dry etch forms a trench penetrating into the laser die through an active portion of the laser die including a laser diode, and where the dry etch partially penetrates through a second substrate of the laser die attached to the active portion of the laser die; and sawing through an un-etched portion of the second substrate from a second direction, opposite the first direction, using a saw blade, where the saw blade forms a tapered or rounded cutting profile in at least a portion of a cut surface of the second substrate, and where a largest width of a cutting portion of the saw blade is greater than a largest width of the dry etch trench.

In an embodiment, the method of forming the integrated package further includes: forming a dielectric-to-dielectric bond between the first bonding layer and the third bonding layer and between the second bonding layer and the third bonding layer; and forming an encapsulant over the interposer, where the encapsulant surrounds the optical die, the laser die, and the optical glue.

In an embodiment, the method of forming the integrated package further includes electrically connecting the interposer to a plurality of external connectors on a side of the interposer opposite the optical die and the laser die.

In an embodiment, electrically connecting the interposer to the plurality of external connectors includes: de-bonding a third substrate from the interposer; forming or attaching a first side of a redistribution structure on a second side of the interposer opposite the optical die and the laser die, where the redistribution structure includes one or more dielectric layers, and one or more metallization layers; and forming external connectors on a second side of the redistribution structure opposite the interposer, where the one or more metallization layers of the redistribution structure electrically connect the interposer to the plurality of external connectors.

In an embodiment, electrically connecting the interposer to the plurality of external connectors includes: forming one or more through-silicon vias (TSVs) through a third substrate attached to a second side of the interposer opposite the optical die and the laser die; and forming external connectors on a side of the third substrate opposite the interposer, where the TSVs electrically connect the interposer to the plurality of external connectors.

In an embodiment, a device includes: one or more integrated packages, where each integrated package includes: an optical die, where the optical die includes one or more photonic integrated circuits (PICs), one or more first coupling waveguides optically connected to at least one of the one or more PICS, and a first bonding layer including a first dielectric and a first metallization layer formed using a damascene or dual damascene process; a laser die, where the laser die includes at least one laser diode, one or more second coupling waveguides, and a second bonding layer including a second dielectric and a second metallization layer formed using a damascene or dual damascene process, and where at least one of the one or more second coupling waveguides is optically connected to the laser diode; an interposer, where the interposer includes a third bonding layer including a third dielectric and a third metallization layer, where the first bonding layer of the optical die is bonded to the third bonding layer of the interposer using metal-to-metal bonding, where the second bonding layer of the laser die is bonded to the third bonding layer of the interposer using metal-to-metal bonding, and where at least one of the one or more first coupling waveguides is optically aligned with at least one of the one or more second coupling waveguides; and an optical glue, where the optical glue fills a gap between the aligned at least one of the one or more first coupling waveguides and the at least one of the one or more second coupling waveguides as an optical transmission medium between the optical die and the laser die.

In an embodiment, the first bonding layer of the optical die and the second bonding layer of the laser die are each further bonded to the third bonding layer of the interposer using a dielectric-to-dielectric bond, where the one or more integrated packages further include an encapsulant, where the encapsulant covers the interposer and surrounds the optical die, the laser die, and the optical glue, and where the encapsulant is in contact with at least one sidewall of the optical die, one sidewall or the laser die, and a top of the optical glue.

In an embodiment, the one or more integrated packages further include a redistribution structure attached to a second side of the interposer opposite the third bonding layer, where the redistribution structure includes one or more layers of dielectric and one or more layers of metallization, and where the one or more layers of metallization electrically connect the interposer to a plurality of external connectors.

In an embodiment, the one or more integrated packages further include a silicon substrate attached to a second side of the interposer opposite the third bonding layer, where the silicon substrate includes through-silicon vias (TSVs) electrically connecting the interposer to a plurality of external connectors.

In an embodiment, at least two sidewalls of the optical die and at least two sidewalls of the laser die include a substantially straight first portion closest to the interposer, a substantially straight second portion furthest from the interposer, and a third portion between the first portion and the second portion that is tapered; where the at least two sidewalls are on opposite sides of the optical die and the laser die, and where at least one of the at least two sidewalls of the optical die intersects with the least one of the one or more first coupling waveguides optically aligned with the at least one of the one or more second coupling waveguides, and where the at least one of the at least two sidewalls of the laser die intersects with the least one of the one or more second coupling waveguides optically aligned with the at least one of the one or more first coupling waveguides; where a first width of the optical die between the first portion of the at least two sidewalls is larger than a second width of the optical die between the second portion of the at least two sidewalls; and where a third width of the laser die between the first portion of the at least two sidewalls is larger than a fourth width of the laser die between the second portion of the at least two sidewalls.

In an embodiment, the one or more integrated packages are integrated horizontally and/or vertically on a redistribution layer (RDL) interconnect, on a silicon interposer, on an RDL interposer, on a local silicon interconnect and a RDL interposer, or on an integrated fan out with one or more additional heterogeneous integrated packages, memories, or dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated package, comprising:
an optical die, wherein the optical die comprises photonic integrated circuits (PICs), electronic integrated circuits (EICs), and one or more first coupling waveguides;
a laser die, wherein the laser die comprises at least one laser diode, and one or more second coupling waveguides;
an interposer, wherein the optical die is bonded to a first side of the interposer using a metal-to-metal bonding, wherein the laser die is bonded to the first side of the interposer using a metal-to-metal bonding, and wherein at least one of the one or more first coupling waveguides is optically aligned with at least one of the one or more second coupling waveguides; and
an optical glue filling a gap between the aligned at least one of the one or more first coupling waveguides and the at least one of the one or more second coupling waveguides.

2. The integrated package of claim 1, further comprising an encapsulant, wherein the encapsulant covers the interposer and surrounds the optical die, the laser die, and the optical glue.

3. The integrated package of claim 1, further comprising a redistribution structure on a second side of the interposer opposite the first side, wherein the redistribution structure comprises one or more layers of dielectric and one or more layers of metallization, and wherein the one or more layers of metallization electrically connect the interposer to a plurality of external connectors.

4. The integrated package of claim 1, further comprising a silicon substrate attached to a second side of the interposer opposite the first side, wherein the silicon substrate comprises through-silicon vias (TSVs) through the silicon substrate and electrically connecting the interposer to a plurality of external connectors.

5. The integrated package of claim 1, wherein at least two sidewalls of the optical die include a substantially straight first portion closest to the interposer, a substantially straight second portion furthest from the interposer, and a third portion between the first portion and the second portion that is tapered;
wherein the at least two sidewalls are on opposite sides of the optical die, and wherein at least one of the at least two sidewalls intersects with the least one of the one or more first coupling waveguides optically aligned with the at least one of the one or more second coupling waveguides; and
wherein a first width of the optical die between the first portion of the at least two sidewalls is larger than a second width of the optical die between the second portion of the at least two sidewalls.

6. The integrated package of claim 5, wherein the third portion is tapered to form a rounded concave profile in the sidewall of the optical die between the first portion and the second portion of the sidewall.

7. The integrated package of claim 1, wherein optical die and the laser die are horizontally spaced between about 5 μm and about 100 μm apart on the interposer, and wherein the optical die and laser die are each further bonded to the interposer using a dielectric-to-dielectric bond.

8. A method of forming an integrated package, the method comprising:
forming a first bonding layer, comprising a first dielectric layer and a first metallization layer, on a first side of an optical die, wherein the optical die comprises photonic integrated circuits (PICs), electronic integrated circuits (EICs), and one or more first coupling waveguides;
forming a second bonding layer, comprising a second dielectric layer and a second metallization layer, on a first side of a laser die, wherein the laser die comprises at least one laser diode and one or more second coupling waveguides;
forming a third bonding layer, comprising a third dielectric layer and a third metallization layer, on a first side of an interposer;
aligning the first side of the optical die and the first side of the laser die on the first side of the interposer, wherein the first bonding layer of the optical die and the second bonding layer of the laser die are in physical contact with the third bonding layer of the interposer, and wherein at least one of the one or more first coupling waveguides is optically aligned with at least one of the one or more second coupling waveguides;
forming a metal-to-metal bond between the first bonding layer and the third bonding layer and between the second bonding layer and the third bonding layer; and
filling a void between the optical die and the laser die with an optical glue.

9. The method of forming the integrated package according to claim 8, further comprising, before aligning the first side of the optical die and the first side of the laser die on the first side of the interposer, a multi-step singulation of the optical die including:
performing a dry etch from a first direction to partially singulate between at least two optical dies, wherein the dry etch forms a trench penetrating into the optical die through an active portion of the optical die, and wherein the dry etch partially penetrates through a first substrate of the optical die attached to the active portion of the optical die; and
sawing through an un-etched portion of the first substrate from a second direction, opposite the first direction, using a saw blade, wherein the saw blade forms a tapered or rounded cutting profile in at least a portion of a cut surface of the first substrate, and wherein a largest width of a cutting portion of the saw blade is greater than a largest width of the dry etch trench.

10. The method of forming the integrated package according to claim 8, wherein the method further comprises, before aligning the first side of the optical die and the first side of the laser die on the first side of the interposer, a multi-step singulation of the laser die including:
performing a dry etch from a first direction to partially singulate between at least two laser dies, wherein the dry etch forms a trench penetrating into the laser die through an active portion of the laser die comprising a laser diode, and wherein the dry etch partially penetrates through a second substrate of the laser die attached to the active portion of the laser die; and
sawing through an un-etched portion of the second substrate from a second direction, opposite the first direction, using a saw blade, wherein the saw blade forms a tapered or rounded cutting profile in at least a portion of a cut surface of the second substrate, and wherein a largest width of a cutting portion of the saw blade is greater than a largest width of the dry etch trench.

11. The method of forming the integrated package according to claim 8, further comprising:
forming a dielectric-to-dielectric bond between the first bonding layer and the third bonding layer and between the second bonding layer and the third bonding layer; and
forming an encapsulant over the interposer, wherein the encapsulant surrounds the optical die, the laser die, and the optical glue.

12. The method of forming the integrated package according to claim 8, further comprising electrically connecting the interposer to a plurality of external connectors on a side of the interposer opposite the optical die and the laser die.

13. The method of forming the integrated package according to claim 12, wherein electrically connecting the interposer to the plurality of external connectors comprises:
de-bonding a third substrate from the interposer;
forming or attaching a first side of a redistribution structure on a second side of the interposer opposite the optical die and the laser die, wherein the redistribution structure comprises one or more dielectric layers, and one or more metallization layers; and
forming external connectors on a second side of the redistribution structure opposite the interposer, wherein the one or more metallization layers of the redistribution structure electrically connect the interposer to the plurality of external connectors.

14. The method of forming the integrated package according to claim 12, wherein electrically connecting the interposer to the plurality of external connectors comprises:
forming one or more through-silicon vias (TSVs) through a third substrate attached to a second side of the interposer opposite the optical die and the laser die; and
forming external connectors on a side of the third substrate opposite the interposer, wherein the TSVs electrically connect the interposer to the plurality of external connectors.

15. A device, comprising:
one or more integrated packages, wherein each integrated package includes:
an optical die, wherein the optical die includes one or more photonic integrated circuits (PICs), one or more first coupling waveguides optically connected to at least one of the one or more PICS, and a first bonding layer comprising a first dielectric and a first metallization layer formed using a damascene or dual damascene process;
a laser die, wherein the laser die includes at least one laser diode, one or more second coupling waveguides, and a second bonding layer comprising a second dielectric and a second metallization layer formed using a damascene or dual damascene process, and wherein at least one of the one or more second coupling waveguides is optically connected to the laser diode;
an interposer, wherein the interposer comprises a third bonding layer comprising a third dielectric and a third metallization layer, wherein the first bonding layer of the optical die is bonded to the third bonding layer of the interposer using metal-to-metal bonding, wherein the second bonding layer of the laser die is bonded to the third bonding layer of the interposer using metal-to-metal bonding, and wherein at least one of the one or more first coupling waveguides is optically aligned with at least one of the one or more second coupling waveguides; and
an optical glue, wherein the optical glue fills a gap between the aligned at least one of the one or more first coupling waveguides and the at least one of the one or more second coupling waveguides as an optical transmission medium between the optical die and the laser die.

16. The device of claim 15, wherein the first bonding layer of the optical die and the second bonding layer of the laser die are each further bonded to the third bonding layer of the interposer using a dielectric-to-dielectric bond, wherein the one or more integrated packages further comprise an encapsulant, wherein the encapsulant covers the interposer and surrounds the optical die, the laser die, and the optical glue, and wherein the encapsulant is in contact with at least one sidewall of the optical die, one sidewall or the laser die, and a top of the optical glue.

17. The device of claim 15, wherein the one or more integrated packages further comprise a redistribution structure attached to a second side of the interposer opposite the third bonding layer, wherein the redistribution structure comprises one or more layers of dielectric and one or more layers of metallization, and wherein the one or more layers of metallization electrically connect the interposer to a plurality of external connectors.

18. The device of claim 15, wherein the one or more integrated packages further comprise a silicon substrate attached to a second side of the interposer opposite the third bonding layer, wherein the silicon substrate comprises through-silicon vias (TSVs) electrically connecting the interposer to a plurality of external connectors.

19. The device of claim 15, wherein at least two sidewalls of the optical die and at least two sidewalls of the laser die include a substantially straight first portion closest to the interposer, a substantially straight second portion furthest from the interposer, and a third portion between the first portion and the second portion that is tapered;
wherein the at least two sidewalls are on opposite sides of the optical die and the laser die, and wherein at least one of the at least two sidewalls of the optical die intersects with the least one of the one or more first coupling waveguides optically aligned with the at least one of the one or more second coupling waveguides, and wherein the at least one of the at least two sidewalls of the laser die intersects with the least one of the one or more second coupling waveguides optically aligned with the at least one of the one or more first coupling waveguides;
wherein a first width of the optical die between the first portion of the at least two sidewalls is larger than a second width of the optical die between the second portion of the at least two sidewalls; and
wherein a third width of the laser die between the first portion of the at least two sidewalls is larger than a fourth width of the laser die between the second portion of the at least two sidewalls.

20. The device of claim 15, wherein the one or more integrated packages are integrated horizontally and/or vertically on a redistribution layer (RDL) interconnect, on a silicon interposer, on an RDL interposer, on a local silicon interconnect and a RDL interposer, or on an integrated fan out with one or more additional heterogeneous integrated packages, memories, or dies.
